(19) United States
(12) Patent Application Publication
(10) Pub. No.: US 2022/0380538 A1
(43) Pub. Date: Dec. 1, 2022

(54) CURABLE COMPOSITION INCLUDING POLYPHENYLENE ETHER, DRY FILM, PREPREG, CURED PRODUCT, LAMINATED BOARD, AND ELECTRONIC COMPONENT

(71) Applicant: TAIYO HOLDINGS CO., LTD., Hiki-gun (JP)

(72) Inventors: Mami NOSAKA, Hiki-gun (JP); Satoko MATSUMURA, Hiki-gun (JP); Nobuhiro ISHIKAWA, Hiki-gun (JP)

(73) Assignee: TAIYO HOLDINGS CO., LTD., Hiki-gun (JP)

(21) Appl. No.: 17/764,470

(22) PCT Filed: Sep. 29, 2020
(86) PCT No.: PCT/JP2020/037037

§ 371 Date: Mar. 28, 2022

(30) Foreign Application Priority Data
Sep. 30, 2019 (JP) 2019-180449
Sep. 30, 2019 (JP) 2019-180450
Jan. 9, 2020 (JP) 2020-002446
Jan. 9, 2020 (JP) 2020-002447

(51) Int. Cl. C08G 65/48; C08K 3/36; C08K 5/3492; C08F 212/08; C08J 5/18; C08K 5/3415; C08K 5/37

(52) U.S. Cl. CPC C08G 65/485; C08K 3/36; C08K 5/3492; C08F 212/08; C08J 5/18; C08K 5/3415; C08K 5/37; C08J 2371/02; C08J 2325/06; C08G 2650/20

(57) ABSTRACT

Provided is a curable composition that is soluble in various solvents (organic solvents other than highly toxic organic solvents, for example, cyclohexanone) while maintaining excellent low dielectric properties, wherein a film obtained by curing the curable composition has excellent mechanical properties. A curable composition, comprising: a polyphenylene ether having a functional group including an unsaturated carbon bond, which is obtained from raw material phenols including phenols satisfying at least condition 1 (having a hydrogen atom at an ortho position and a para position), and having a slope calculated by a conformation plot of less than 0.6; and at least one of a compound containing at least one maleimide group in one molecule, a triazine-based compound containing at least one thiol group, and crosslinked polystyrene particles.

### TECHNICAL FIELD

The present invention relates to a curable composition including a polyphenylene ether, and further relates to a dry film, a prepreg, a cured product, a laminated board, and an electronic component using the curable composition.

### BACKGROUND ART

With the spread of large-capacity high-speed communication typified by a fifth generation communication system (5G), millimeter wave radars for an advanced driving assistant system (ADAS) of automobiles, and the like, the higher frequency of signals on communication devices has been progressed.

However, when an epoxy resin or the like is used as the wiring board material, the relative permittivity (Dk) and the dielectric loss tangent (Df) are not sufficiently low, and therefore the transmission loss derived from the dielectric loss increases as the frequency increases, causing problems such as signal attenuation and heat generation. Therefore, polyphenylene ethers excellent in low dielectric properties have been used.

In addition, Non Patent Literature 1 has proposed a polyphenylene ether having heat resistance improved by introducing an allyl group into a molecule of the polyphenylene ether to form a thermosetting resin.

### CITATION LIST

### Non Patent Literature

Non Patent Literature 1: J. Nunoshige, H. Akahoshi, Y Shibasaki, M. Ueda, J. Polym. Sci. Part A: Polym. Chem. 2008, 46, 5278-3223

### SUMMARY OF INVENTION

### Technical Problem

However, the soluble solvent of polyphenylene ether is limited, and the polyphenylene ether obtained by the method of Non Patent Literature 1 also dissolves only in a highly toxic solvent such as chloroform and toluene. Therefore, the resin varnish (curable composition) including such a polyphenylene ether is problematic in that it is difficult to handle the resin varnish and to control solvent exposure in a step of forming and curing a coating film as in wiring board applications.

In addition, it is desired that polyphenylene ether satisfies various mechanical properties when used as a wiring board.

An object of the present invention is to provide a curable composition that is soluble in various solvents (organic solvents other than highly toxic organic solvents, for example, cyclohexanone) while maintaining excellent low dielectric properties, wherein a film obtained by curing the curable composition has excellent mechanical properties.

### Solution to Problem

The present inventors have found that the above problem can be solved by employing a curable composition including a polyphenylene ether having a branched structure and a predetermined component, and have completed the present invention. That is, the present invention is as follows.

The present invention (1) is a curable composition, comprising.

a polyphenylene ether having a functional group including an unsaturated carbon bond, the polyphenylene ether being obtained from raw material phenols including phenols satisfying at least condition 1, and having less than 0.6 of a slope calculated by a conformation plot; and

at least any one of a compound containing at least one maleimide group in one molecule, a triazine-based compound containing at least one thiol group, and crosslinked polystyrene particles. (Condition 1) Including a hydrogen atom at the ortho position and the para position.

The present invention (2) is the curable composition of the present invention (1), wherein the polyphenylene ether further includes a hydroxyl group, and which comprises a styrene copolymer having a functional group capable of reacting with the hydroxyl group.

The present invention (3) is the curable composition of the present invention (1) or (2), comprising trialkenyl isocyanurate.

The present invention (4) is a dry film or a preproduction obtained by applying the curable composition of any one of the inventions (1) to (3) to a base material or impregnating the base material with the curable composition of any one of the inventions (1) to (3).

The present invention (5) is a cured product obtained by curing the curable composition of any one of the inventions (1) to (3).

The present invention (6) is a laminated board, comprising the cured product of the invention (5).

The present invention (7) is an electronic component comprising the cured product of the invention (5).

### Advantageous Effects of Invention

The present invention can provide a curable composition that is soluble in various solvents (organic solvents other than highly toxic organic solvents, for example, cyclohexanone) while maintaining excellent low dielectric properties, wherein a film obtained by curing the curable composition has excellent mechanical properties.

### DESCRIPTION OF EMBODIMENTS

In the present description, it is premised that all descriptions of Japanese Patent Application No. 2019-180449, Japanese Patent Application No. 2019-180450, Japanese Patent Application No. 2020-002446, and Japanese Patent Application No. 2020-002447 are cited in its entirety by reference and incorporated in the present description.

Hereinafter, a curable composition including the polyphenylene ether of the present invention will be described, but the present invention is not limited thereto at all.

When isomers are present in the compounds described, all isomers that may be present are usable in the present invention unless otherwise specified.

In the present invention, phenols that can be used as a raw material of a polyphenylene ether (PPE) and can be a constituent unit of the polyphenylene ether are collectively referred to as “raw material phenols”.

In the present invention, when “ortho position”, “para position”, or the like is described in explaining raw material phenols, unless otherwise specified, the position of the phenolic hydroxyl group is used as a reference (ipso position).

In the present invention, simply described “ortho position” or the like indicates “at least one of ortho positions” or the like. Therefore, as long as there is no particular contradiction, the simply described “ortho position” may be interpreted as indicating any one of the ortho positions or may be interpreted as indicating both of the ortho positions.

In the present invention, a polyphenylene ether in which a part of or all functional groups (for example, a hydroxyl group) of the polyphenylene ether are modified may be simply referred to as a “polyphenylene ether”. Therefore, the “polyphenylene ether” includes both an unmodified polyphenylene ether and a modified polyphenylene ether as long as there is no particular contradiction.

In the present description, monovalent phenols are mainly disclosed as the raw material phenols; however, polyvalent phenols may be used as the raw material phenols as long as the effect of the present invention is not inhibited.

In the present description, a “resin composition” may be used in the sense of a “curable composition”.

In the present description, when the upper limit and the lower limit of the numerical range are described separately, all combinations of each lower limit and each upper limit are substantially described as long as there is no contradiction.

<<<<Curable Composition>>>>

The curable composition of the present invention includes a polyphenylene ether having a branched structure and a predetermined additive component.

The polyphenylene ether having a branched structure has, for example, a functional group including an unsaturated carbon bond. The predetermined additive component is, for example, at least one or more selected from the group consisting of a compound containing at least one maleimide group in one molecule, a triazine-based compound containing at least one thiol group, and crosslinked polystyrene particles.

In addition, the polyphenylene ether having a branched structure may have a hydroxyl group, and the curable composition may include a styrene copolymer having a functional group capable of reacting with the hydroxyl group of the polyphenylene ether.

Furthermore, the curable composition of the present invention may include other components as long as the effects of the present invention are not impaired. For example, trialkenyl isocyanurate or the like that is a crosslinkable curing agent may be included.

Each component will be described below.

<<<Polyphenylene Ether>>>

The polyphenylene ether constituting the curable composition of the present invention is a polyphenylene ether, which is obtained from raw material phenols including a phenol satisfying at least condition 1, and having a branched structure. Such a polyphenylene ether is referred to as a predetermined polyphenylene ether.

(Condition 1)

Including a hydrogen atom at the ortho position and the para position.

The phenols (for example, phenols (A) and phenols (B) to be described later) satisfying the condition 1 have a hydrogen atom at the ortho position, and therefore an ether bond can be formed not only at the ipso position and the para position but also at the ortho position when oxidative polymerization is performed with the phenols, thus allowing forming a branched chain structure.

As described above, the polyphenylene ether having a branched structure may be referred to as a branched polyphenylene ether.

As described above, a part of the structure of the predetermined polyphenylene ether is branched by a benzene ring in which at least three positions of an ipso position, an ortho position, and a para position are ether-bonded. The predetermined polyphenylene ether is considered to be, for example, a polyphenylene ether compound having at least a branched structure as represented by formula (i) in the skeleton.

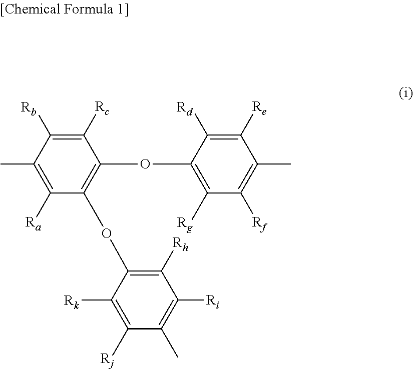

In the formula (i), Rₐ to Rₖ each represent a hydrogen atom or a hydrocarbon group having 1 to 15 carbon atoms (preferably, 1 to 12 carbon atoms).

Herein, the raw material phenols constituting the predetermined polyphenylene ether may include other phenols that unsatisfy the condition 1 as long as the effect of the present invention is not impaired.

Examples of such other phenols include phenols (C) and phenols (D) described later, and phenols having no hydrogen atom at the para position. Particularly, phenols (C) and phenols (D) to be described later are polymerized in a linear form with formation of an ether bond at the ipso position and the para position during oxidative polymerization. Therefore, in order to increase the molecular weight of the polyphenylene ether, it is preferable to further include phenols (C) and phenols (D) as raw material phenols.

In addition, the predetermined polyphenylene ether may have a functional group including an unsaturated carbon bond. Having such a functional group further improves various properties of the cured product by the effect of imparting crosslinkability and excellent reactivity.

In the present invention, an “unsaturated carbon bond” refers to an ethylenic or acetylenic carbon-carbon multiple bond (double bond or triple bond) unless otherwise specified.

The functional group including such an unsaturated carbon bond is not particularly limited, and is preferably an alkenyl group (for example, a vinyl group or an allyl group), an alkynyl group (for example, ethynyl groups), or a (meth)acryloyl group, more preferably a vinyl group, an allyl group, or a (meth)acryloyl group from the viewpoint of excellent curability, and still more preferably an allyl group from the viewpoint of excellent low dielectric properties. The number of carbon atoms in these functional groups having an unsaturated carbon bond can be, for example, 15 or less, 10 or less, 8 or less, 5 or less, and 3 or less.

The method of introducing such a functional group including an unsaturated carbon bond into a predetermined polyphenylene ether is not particularly limited, and examples thereof include the following [Method 1] and [Method 2].

[Method 1]

Method 1 is a method of:

including phenols (A) satisfying at least both of the following condition 1 and the following condition 2 (form 1); or

including a mixture of phenols (B) satisfying at least the following condition 1 and unsatisfying the following condition 2 and phenols (C) unsatisfying the following condition 1 and satisfying the following condition 2 (form 2),

as raw material phenols.

(Condition 1)

Including a hydrogen atom at the ortho position and the para position.

(Condition 2)

Including a hydrogen atom at the para position, and including a functional group including an unsaturated carbon bond.

The method 1 can provide a predetermined polyphenylene ether having a functional group including an unsaturated carbon bond derived from raw material phenols.

[Method 2]

Method 2 is a method of:

modifying a terminal hydroxyl group of a branched polyphenylene ether into a functional group including an unsaturated carbon bond to provide a terminal-modified polyphenylene ether.

The method 2 can provide a predetermined polyphenylene ether into which the functional group including an unsaturated carbon bond is introduced, although the raw material phenols have no functional group including an unsaturated carbon bond.

[Method 1] and [Method 2] may be performed simultaneously.

<<Predetermined Polyphenylene Ether Obtained by Method 1>>

The predetermined polyphenylene ether obtained by Method 1 uses at least phenols satisfying the condition 2 (for example, any of phenols (A) or phenols (C)) as raw material phenols, and therefore has crosslinkability due to a hydrocarbon group including at least an unsaturated carbon bond. When the predetermined polyphenylene ether has such a hydrocarbon group including an unsaturated carbon bond, it is also possible to perform modification such as epoxidation by using a compound that reacts with the hydrocarbon group and has a reactive functional group such as an epoxy group.

That is, the predetermined polyphenylene ether obtained by the method 1 is, for example, a polyphenylene ether having at least a branched structure as represented by formula (i) in the skeleton, and is considered to be a compound having a hydrocarbon group including at least one unsaturated carbon bond as a functional group. Specifically, the compound is considered to be one in which at least one of Rₐ to Rₖ in the above formula (i) is a hydrocarbon group having an unsaturated carbon bond.

Particularly, in the above form 2, from an industrial and economic point of view, it is preferable that the phenols (B) are at least any one of o-cresol, 2-phenylphenol, 2-dodecylphenol, and phenol, and the phenols (C) are 2-allyl-6-methylphenol.

Hereinafter, the phenols (A) to (D) will be described in more detail.

As described above, the phenols (A) are phenols that satisfy both conditions 1 and 2, that is, phenols having hydrogen atoms at the ortho and para positions and having a functional group including an unsaturated carbon bond, and preferably phenols (a) represented by the following formula (1).

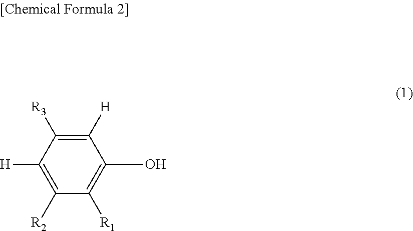

In the formula (1), R₁ to R₃ each represents a hydrogen atom or a hydrocarbon group having 1 to 15 carbon atoms. At least one of R₁ to R₃ is a hydrocarbon group having an unsaturated carbon bond. From the viewpoint of facilitating polymerization during oxidation polymerization, the hydrocarbon group preferably has 1 to 12 carbon atoms.

Examples of the phenols (a) represented by the formula (1) include o-vinylphenol, m-vinylphenol, o-allylphenol, m-allylphenol, 3-vinyl-6-methylphenol, 3-vinyl-6-ethylphenol, 3-vinyl-5-methylphenol, 3-vinyl-5-ethylphenol, 3-allyl-6-methylphenol, 3-allyl-6-ethylphenol, 3-allyl-5-methylphenol, and 3-allyl-5-ethylphenol. The phenols represented by the formula (1) may be used singly or may be used in combination of two or more.

As described above, the phenols (B) are phenols that satisfy the condition 1 and unsatisfy the condition 2, that is, phenols having hydrogen atoms at the ortho and para positions and having no functional group including an unsaturated carbon bond, and preferably phenols (b) represented by the following formula (2).

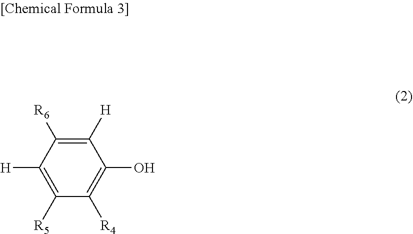

In the formula (2), R₄ to R₆ each represents a hydrogen atom or a hydrocarbon group having 1 to 15 carbon atoms. R₄ to R₆ have no unsaturated carbon bond. From the viewpoint of facilitating polymerization during oxidation polymerization, the hydrocarbon group preferably has 1 to 12 carbon atoms.

Examples of the phenols (b) represented by the formula (2) include phenol, o-cresol, m-cresol, o-ethylphenol, m-ethylphenol, 2,3-xylenol, 2,5-xylenol, 3,5-xylenol, o-tert-butylphenol, m-tert-butylphenol, o-phenylphenol, m-phenylphenol, and 2-dodecylphenol. The phenols represented by the formula (2) may be used singly or may be used in combination of two or more.

As described above, the phenols (C) are phenols that unsatisfy the condition 1 and satisfy the condition 2, that is, phenols having hydrogen atoms at the para position, having no hydrogen atoms at the ortho position, and having a functional group including an unsaturated carbon bond, and preferably phenols (c) represented by the following formula (3).

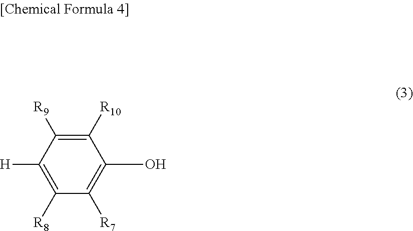

In the formula (3), R₇ and R₁₀ are a hydrocarbon group having 1 to 15 carbon atoms, and R₈ and R₉ are a hydrogen atom or a hydrocarbon group having 1 to 15 carbon atoms. At least one of R₇ to R₁₀ is a hydrocarbon group having an unsaturated carbon bond. From the viewpoint of facilitating polymerization during oxidation polymerization, the hydrocarbon group preferably has 1 to 12 carbon atoms.

Examples of the phenols (c) represented by the formula (3) include 2-allyl-6-methylphenol, 2-allyl-6-ethylphenol, 2-allyl-6-phenylphenol, 2-allyl-6-styrylphenol, 2,6-divinylphenol, 2,6-diallylphenol, 2,6-diisopropenylphenol, 2,6-dibutenylphenol, 2,6-diisobutenylphenol, 2,6-diisopentenylphenol, 2-methyl-6-styrylphenol, 2-vinyl-6-methylphenol, and 2-vinyl-6-ethylphenol. The phenols represented by the formula (3) may be used singly or may be used in combination of two or more.

As described above, the phenols (D) are phenols that have hydrogen atoms at the para position, having no hydrogen atoms at the ortho position, and having no functional group including an unsaturated carbon bond, and preferably phenols (d) represented by the following formula (4).

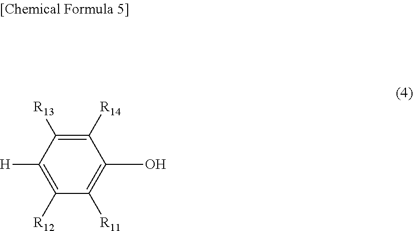

In the formula (4), R₁₁ and R₁₄ are a hydrocarbon group having 1 to 15 carbon atoms and having no unsaturated carbon bond, and R₁₂ and R₁₃ are a hydrogen atom or a hydrocarbon group having 1 to 15 carbon atoms and having no unsaturated carbon bond. From the viewpoint of facilitating polymerization during oxidation polymerization, the hydrocarbon group preferably has 1 to 12 carbon atoms.

Examples of the phenols (d) represented by the formula (4) include 2,6-dimethylphenol, 2,3,6-trimethylphenol, 2-methyl-6-ethylphenol, 2-ethyl-6-n-propylphenol, 2-methyl-6-n-butylphenol, 2-methyl-6-phenylphenol, 2,6-diphenylphenol, and 2,6-ditolylphenol. The phenols represented by the formula (4) may be used singly or may be used in combination of two or more.

Herein, in the present invention, examples of the hydrocarbon group include an alkyl group, a cycloalkyl group, an aryl group, an alkenyl group, and an alkynyl group. An alkyl group, an aryl group, and an alkenyl group are preferable. Examples of the hydrocarbon group having an unsaturated carbon bond include an alkenyl group and an alkynyl group. These hydrocarbon groups may be linear or branched.

<<Predetermined Polyphenylene Ether Obtained by Method 2>>

The predetermined polyphenylene ether obtained by the method 2 is a terminal-modified branched polyphenylene ether.

Such a terminal-modified branched polyphenylene ether has a branched structure and a terminal hydroxyl group is modified, thus allowing providing a cured product that is soluble in various solvents and has lower dielectric properties. In addition, since the terminal-modified branched polyphenylene ether has an unsaturated carbon bond at a terminal position, reactivity is extremely improved, and therefore performance of the resulting cured product is further improved.

When the terminal hydroxyl group is modified with the modifying compound, an ether bond or an ester bond is typically formed between the terminal hydroxyl group and the modifying compound.

Herein, the modifying compound is not particularly limited as long as it includes a functional group having an unsaturated carbon bond and can react with a phenolic hydroxyl group in the presence or absence of a catalyst.

Preferred examples of the modifying compound include an organic compound represented by the following formula (11).

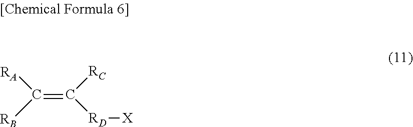

In the formula (11), R_{A}, R_{B}, and R_{C} are each independently hydrogen or a hydrocarbon group having 1 to 9 carbon atoms, R_{D} is a hydrocarbon group having 1 to 9 carbon atoms, and X is a group capable of reacting with a phenolic hydroxyl group, such as F, Cl, Br, I, or CN.

In addition, from another viewpoint, preferable examples of the modifying compound include an organic compound represented by the following formula (11-1).

[Chemical Formula 7]

R—X (11-1)

In the formula (11-1), R is a vinyl group, an allyl group, or a (meth)acryloyl group, and X is a group capable of reacting with a phenolic hydroxyl group, such as F, Cl, Br, or I.

The modification of the terminal hydroxyl group in the branched polyphenylene ether can be confirmed by comparing the hydroxyl values of the branched polyphenylene ether and the terminal-modified branched polyphenylene ether. Apart of hydroxyl groups in the terminal-modified branched polyphenylene ether may remain as being unmodified.

The reaction temperature, the reaction time, the presence or absence of the catalyst, the type of the catalyst, and the like in modification can be appropriately designed. Two or more of compounds may be used as the modifying compound.

When the predetermined polyphenylene ether is obtained by the method 2, the branched polyphenylene ether before modification may be a branched polyphenylene ether containing an unsaturated carbon bond (the predetermined polyphenylene ether obtained by the method 1 described above) or a branched polyphenylene ether including no unsaturated carbon bond.

The branched polyphenylene ether containing no unsaturated carbon bond may be a polyphenylene ether obtained from raw material phenols that include phenols satisfying at least the following condition 1 and include no phenols satisfying the following condition Z.

(Condition 1)

Including a hydrogen atom at the ortho position and the para position.

(Condition Z)

Including a functional group having an unsaturated carbon bond.

As described above, the branched polyphenylene ether including no unsaturated carbon bond includes, as an essential component, phenols (for example, phenols (B)) that satisfy the condition 1 and unsatisfy the condition Z.

The branched polyphenylene ether containing no unsaturated carbon bond may include, as additional raw material phenols, other phenols that unsatisfy the condition Z.

Examples of other phenols that unsatisfy the condition Z include: phenols (D) that are phenols having a hydrogen atom at the para position, no hydrogen atom at the ortho position, and no functional group including an unsaturated carbon bond; and phenols having no hydrogen atom at the para position and no functional group including an unsaturated carbon bond.

In order to increase the molecular weight of the polyphenylene ether, it is preferable to further include the phenols (D) as raw material phenols in the predetermined polyphenylene ether containing no unsaturated carbon bond.

When the branched polyphenylene ether containing no unsaturated carbon bond is used as a raw material, no phenols satisfying the condition Z is included as raw material phenols, and therefore no unsaturated carbon bond is introduced into the side chain. Curability is imparted by modifying a part or all of the terminal hydroxyl groups of the polyphenylene ether obtained by oxidative polymerization of the raw material phenols to functional groups having an unsaturated carbon bond. As a result, deterioration in low dielectric properties, light resistance and environmental resistance due to the terminal hydroxyl group is suppressed, and the unsaturated carbon bond at the terminal site has excellent reactivity, thereby affording high strength and excellent crack resistance to a cured product with a crosslinkable curing agent described later.

When the branched polyphenylene ether contains no unsaturated carbon bond, the ratio of the phenols satisfying the condition 1 and unsatisfying the condition Z to the total of the raw material phenols is, for example, 10 mol % or more.

Herein, examples of the hydrocarbon group including no functional group having an unsaturated carbon bond include an alkyl group, a cycloalkyl group, and an aryl group. These hydrocarbon groups may be linear or branched.

When the predetermined polyphenylene ether as described above is used as a component of the curable composition, one type thereof may be used, or two or more types thereof may be used.

The ratio of the phenols satisfying the condition 1 to the total of the raw material phenols used in the synthesis of the predetermined polyphenylene ether is preferably 1 to 50 mol %.

In addition, the phenols satisfying the condition 2 may not be used; however, when used, the ratio of the phenols satisfying the condition 2 to the total of the raw material phenols is preferably 0.5 to 99 mol %, and more preferably 1 to 99 mol %.

<<Content of Predetermined Polyphenylene Ether>>

The content of the predetermined polyphenylene ether in the curable composition of the present invention is typically 5 to 30% by mass or 10 to 20% by mass based on the total solid content of the composition. In addition, from another point of view, the content of the predetermined polyphenylene ether in the curable composition is 20 to 60% by mass based on the total solid content of the composition.

The solid content in the curable composition means components constituting the composition other than the solvent (particularly, organic solvent), or the mass or volume thereof

<<Physical Properties and Properties of Predetermined Polyphenylene Ether>>

<Degree of Branching>

The branched structure (degree of branching) of the predetermined polyphenylene ether can be confirmed based on the following analysis procedure.

(Analysis Procedure)

Chloroform solutions of polyphenylene ethers are prepared at intervals of 0.1, 0.15, 0.2, and 0.25 mg/mL, then a graph of the refractive index difference and the concentration is created while delivering the solution at 0.5 mL/min, and the refractive index increment dn/dc is calculated from the slope. Then, the absolute molecular weight is measured under the following apparatus operating conditions. With reference to the chromatogram of the RI detector and the chromatogram of the MALS detector, a regression line by the least squares method is obtained from a logarithmic graph (conformation plot) of the molecular weight and the rotation radius, and the slope thereof is calculated.

(Measurement Conditions)

Apparatus name: HLC8320GPC

Mobile phase: chloroform

Column:

$$TOSOH TSK guardcolumn HH \text{R-H} \\ + TSKgelGMHH \text{R-H} ( 2 pieces ) \\ + TSKgelG 2500 HHR$$

Flow rate: 0.6 mL/min

Detector: DAWN HELEOS (MALS detector)
+Optilab rEX (RI detector, wavelength 254 nm)

Sample concentration: 0.5 mg/mL

Sample solvent: same as mobile phase/Dissolving 5 mg of sample in 10 mL of mobile phase

Injection amount: 200 μL

Filter: 0.45 μm

STD reagent: standard polystyrene Mw 37900

STD concentration: 1.5 mg/mL

STD solvent: same as mobile phase/Dissolving 15 mg of sample in 10 mL of mobile phase

Analysis time: 100 min

In the resin having the same absolute molecular weight, the distance (rotation radius) from the center of gravity to each segment decreases as the branching of the polymer chain progresses. Therefore, the slope of the logarithmic plot of the absolute molecular weight and the radius of rotation obtained by GPC-MALS indicates the degree of branching, and the smaller slope means the more progress of the branching. In the present invention, the smaller slope calculated from the above conformation plot means the more branching of the polyphenylene ether, and the larger slope means the less branching of the polyphenylene ether.

In the predetermined polyphenylene ether constituting the curable composition of the present invention, the above slope is less than 0.6, and is preferably 0.55 or less, 0.50 or less, 0.45 or less, 0.40 or less, or 0.35 or less. When the above slope is in this range, it is considered that the polyphenylene ether has sufficient branching. The lower limit of the above slope is not particularly limited, and is, for example, 0.05 or more, 0.10 or more, 0.15 or more, or 0.20 or more.

The slope of the conformation plot can be adjusted by changing the temperature, the catalyst amount, the stirring rate, the reaction time, the oxygen supply amount, and the solvent amount in the synthesis of the polyphenylene ether. More specifically, increasing the temperature, increasing the catalyst amount, increasing the stirring rate, increasing the reaction time, increasing the oxygen supply amount, and/or decreasing the solvent amount tend to decrease the slope of the conformation plot (the polyphenylene ether more easily branches).

<Molecular Weight of Predetermined Polyphenylene Ether>

The predetermined polyphenylene ether constituting the curable composition of the present invention preferably has a number average molecular weight of 2000 to 30000, more preferably 5000 to 30000, still more preferably 8000 to 30000, and particularly preferably 8000 to 25000. The molecular weight having such a range can improve the film formability of the curable resin composition while solubility in a solvent is maintained. Furthermore, the predetermined polyphenylene ether constituting the curable composition of the present invention preferably has a polydispersity index (PDI: weight average molecular weight/number average molecular weight) of 1.5 to 20.

In the present invention, the number average molecular weight and the weight average molecular weight are obtained by measurement with gel permeation chromatography (GPC) and conversion by a calibration curve prepared with standard polystyrene.

<Hydroxyl Value of Predetermined Polyphenylene Ether>

The hydroxyl value of the predetermined polyphenylene ether constituting the curable composition of the present invention is preferably 15.0 or less, more preferably 2 or more and 10 or less, and still more preferably 3 or more and 8 or less when the number average molecular weight (Mn) is in the range of 2000 to 30000. In addition, from another point of view, the hydroxyl value of the predetermined polyphenylene ether may be 7.0 or more when the number average molecular weight (Mn) is 10000 or more. In other words, when the number average molecular weight (Mn) is 5000 or more, the hydroxyl value may be 14.0 or more, and when the number average molecular weight (Mn) is 20000 or more, the hydroxyl value of the polyphenylene ether may be 3.5 or more.

When the predetermined polyphenylene ether is the predetermined polyphenylene ether obtained by the method 2 and so on, the hydroxyl value may be lower than the above value.

<Solvent Solubility of Predetermined Polyphenylene Ether>1 g of the predetermined polyphenylene ether constituting the curable composition of the present invention is preferably soluble in 100 g of cyclohexanone (more preferably, 100 g of cyclohexanone, DMF, and PMA) at 25° C. Here, “1 g of polyphenylene ether is soluble in 100 g of a solvent (for example, cyclohexanone)” means that turbidity and precipitation cannot be visually confirmed when 1 g of polyphenylene ether and 100 g of a solvent are mixed. This predetermined polyphenylene ether is more preferably soluble in an amount of 1 g or more in 100 g of cyclohexanone at 25° C.

The predetermined polyphenylene ether constituting the curable composition of the present invention has a branched structure, thereby improving solubility in various solvents and dispersibility and compatibility between components (crosslinked polystyrene particles, maleimide compounds, reactive styrene copolymers, and other components) in the composition. Therefore, since each component in the composition is uniformly dissolved or dispersed, a uniform cured product can be obtained. As a result, this cured product is extremely excellent in mechanical properties and the like. Particularly, the predetermined polyphenylene ether can be crosslinked with each other or with a maleimide compound. As a result, the obtained cured product is better in mechanical properties, low thermal expansion and so on.

<<Method of Producing Predetermined Polyphenylene Ether>>

The predetermined polyphenylene ether constituting the curable composition of the present invention can be produced by applying a conventionally known method of synthesizing a polyphenylene ether (polymerization conditions, presence or absence of catalyst, type of catalyst, and the like), except that specific raw material phenols are used.

Then, an example on the method of producing this predetermined polyphenylene ether will be described.

The predetermined polyphenylene ether can be produced by, for example, preparing a polymerization solution including specific phenols, a catalyst, and a solvent (polymerization solution preparation step), passing oxygen through at least the solvent (oxygen supply step), and oxidatively polymerizing phenols in the polymerization solution including oxygen (polymerization step).

Hereinafter, the polymerization solution preparation step, the oxygen supply step, and the polymerization step will be described. Each step may be continuously performed, a part or all of a certain step and a part or all of another step may be simultaneously performed, or a certain step may be stopped and another step may be performed during the stop of the certain step. For example, the oxygen supply step may be performed during the polymerization solution preparation step or the polymerization step. In addition, the method of producing a polyphenylene ether of the present invention may include other steps as necessary. Examples of the other steps include a step of extracting the polyphenylene ether obtained in the polymerization step (for example, a step of performing reprecipitation, filtration, and drying), and the above modification step.

<Polymerization Solution Preparation Step>

The polymerization solution preparation step is a step of mixing each of the raw materials including phenols to be polymerized in the polymerization step described later to prepare a polymerization solution. Examples of the raw material of the polymerization solution include raw material phenols, catalysts, and solvents.

(Catalyst)

The catalyst is not particularly limited, and may be an appropriate catalyst used in the oxidative polymerization of the polyphenylene ether.

Examples of the catalyst include an amine compound, and a metal amine compound which is composed of a heavy metal compound such as copper, manganese, or cobalt and an amine compound such as tetramethylethylenediamine, and particularly, in order to obtain a copolymer having a sufficient molecular weight, it is preferable to use a copper-amine compound in which a copper compound is coordinated to an amine compound. Only one type of catalyst may be used, or two or more types may be used.

The content of the catalyst is not particularly limited, and may be 0.1 to 0.6 mol % with respect to the total amount of the raw material phenols in the polymerization solution.

Such a catalyst may be previously dissolved in an appropriate solvent.

(Solvent)

The solvent is not particularly limited, and may be an appropriate solvent used in the oxidative polymerization of the polyphenylene ether. It is preferable to use a solvent capable of dissolving or dispersing the phenolic compound and the catalyst.

Specific examples of the solvent include: aromatic hydrocarbons such as benzene, toluene, xylene, and ethylbenzene; halogenated aromatic hydrocarbons such as chloroform, methylene chloride, chlorobenzene, dichlorobenzene, and trichlorobenzene; nitro compounds such as nitrobenzene; methyl ethyl ketone (MEK), cyclohexanone, tetrahydrofuran, ethyl acetate, N-methyl-2-pyrrolidone (NMP), N,N-dimethylformamide (DMF), propylene glycol monomethyl ether acetate (PMA), and diethylene glycol monoethyl ether acetate (CA). Only one type of solvent may be used, or two or more types may be used.

Examples of the solvent may include water and a solvent compatible with water.

The content of the solvent in the polymerization solution is not particularly limited, and may be appropriately adjusted.

(Other Raw Materials)

The polymerization solution may include other raw materials as long as the effect of the present invention is not impaired.

<Oxygen Supply Step>

The oxygen supply step is a step of passing an oxygen-containing gas into a polymerization solution.

The passing time of the oxygen gas and the oxygen concentration in the oxygen-containing gas to be used can be appropriately changed according to the atmospheric pressure, the atmospheric temperature, and the like.

<Polymerization Step>

The polymerization step is a step of oxidatively polymerizing phenols in a polymerization solution under a situation where oxygen is supplied into the polymerization solution.

Specific polymerization conditions are not particularly limited, and for example, stirring may be performed under conditions of 25 to 100° C. and 2 to 24 hours.

In the production of a predetermined polyphenylene ether through the steps as described above, a specific method of introducing a functional group including an unsaturated carbon bond into a branched polyphenylene ether can be understood with reference to the method 1 and the method 2. That is, a predetermined polyphenylene ether having a functional group including an unsaturated carbon bond can be obtained by specifying the type of the raw material phenols or further providing a step (modification step) of modifying the terminal hydroxyl group after the polymerization step, and so on.

<<<Triazine-Based Compound Having Thiol Group>>>

The triazine-based compound having a thiol group is not particularly limited as long as it is a compound containing a triazine ring and containing at least one (preferably two or more) thiol group in one molecule (so-called triazine thiols), and a known conventional compound can be used.

Using a triazine-based compound containing a thiol group and a predetermined polyphenylene ether can provide the effect of the present invention by crosslinking the predetermined polyphenylene ether and developing a property derived from a triazine ring, without inhibiting low dielectric properties and the like of the predetermined polyphenylene ether.

In addition, the triazine-based compound containing a thiol group may have a functional group other than a thiol group (for example, a functional group including an amino group or an unsaturated carbon bond).

The triazine-based compound containing a thiol group is preferably a compound represented by the following formula (Y).

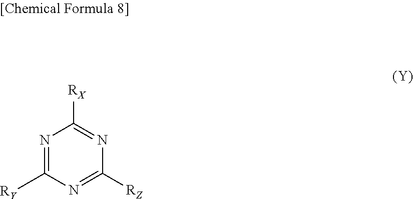

R_{X}, R_{Y}, and R_{Z} in the formula each independently represent a —SH group or a —NR_{α}R_{β} group. At least one of R_{X1}, R_{X2}, and R_{X3} is a —SH group, and preferably two or more of R_{X1}, R_{X2}, and R_{X3} are a —SH group. R_{α} and R_{β} each independently represent a hydrogen atom or a hydrocarbon group having 1 to 15 (preferably 1 to 12, more preferably 1 to 6) carbon atoms. R_{α} and R_{β} may have an unsaturated carbon bond.

Specific examples of the triazine-based compound containing a thiol group can include 1,3,5-triazine-2,4,6-trithiol(thiocyanuric acid), 6-dibutylamino-1,3,5-triazine-2,4-dithiol, 6-diallylamino-1,3,5-triazine-2,4-dithiol, 6-dioctylamino-1,3,5-triazine-2,4-dithiol, 6-dilauramino-1,3,5-triazine-2,4-dithiol, 6-stearylamino-1,3,5-triazine-2,4-dithiol, 6-oleylamino-1,3,5-triazine-2,4-dithiol, and 6-anilino-1,3,5-triazine-2,4-dithiol.

The triazine-based compound containing a thiol group may be in the form of a salt (for example, an alkali metal salt such as a sodium salt, or an ammonium salt).

Only one type of triazine-based compound containing a thiol group may be used, or two or more types may be used.

<<Content of Triazine-Based Compound Containing Thiol Group>>

The content of the triazine-based compound containing a thiol group can be typically 0.01 to 20% by mass, 0.05 to 10% by mass, 0.1 to 5% by mass, or 0.4 to 1.5% by mass, based on the total solid content in the curable composition. In addition, from another viewpoint, the content of the triazine-based compound containing a thiol group/the content of the predetermined polyphenylene ether can be 0.1 to 50, 0.5 to 40, 1 to 30, or 3 to 12 based on the solid content in the curable composition.

<<<Maleimide Compound>>>

The maleimide compound is not particularly limited as long as it contains at least one maleimide group in one molecule.

Examples of the maleimide compound include:

(1) monofunctional aliphatic/alicyclic maleimide;

(2) monofunctional aromatic maleimide;

(3) polyfunctional aliphatic/alicyclic maleimide; and

(4) polyfunctional aromatic maleimide.

<<(1) Monofunctional Aliphatic/Alicyclic Maleimide>>

Examples of the monofunctional aliphatic/alicyclic maleimide (1) include N-methylmaleimide, N-ethylmaleimide, and a reaction product of maleimide carboxylic acid and tetrahydrofurfuryl alcohol disclosed in JP 11-302278 A.

<<(2) Monofunctional Aromatic Maleimide>>

Examples of the monofunctional aromatic maleimide (2) include N-phenylmaleimide and N-(2-methylphenyl)maleimide.

<<(3) Polyfunctional Aliphatic/Alicyclic Maleimide>>

Examples of the polyfunctional aliphatic/alicyclic maleimide (3) include: N,N′-methylenebismaleimide, N,N′-ethylene bismaleimide, a maleimide ester compound having an isocyanurate skeleton obtained by dehydration esterification of tris(hydroxyethyl)isocyanurate and an aliphatic/alicyclic maleimide carboxylic acid, isocyanuric skeleton polymaleimides such as a maleimide urethane compound having an isocyanurate skeleton obtained by urethanizing tris(carbamate hexyl)isocyanurate and an aliphatic/alicyclic maleimide alcohol, isophorone bisurethane bis(N-ethylmaleimide), triethylene glycol bis(maleimidoethyl carbonate), aliphatic/alicyclic polymaleimide ester compounds obtained by dehydration esterification of an aliphatic/alicyclic maleimide carboxylic acid and various aliphatic/alicyclic polyols or transesterification reaction of an aliphatic/alicyclic maleimide carboxylic acid ester and various aliphatic/alicyclic polyols, aliphatic/alicyclic polymaleimide ester compounds obtained by an ether ring opening reaction of an aliphatic/alicyclic maleimide carboxylic acid and various aliphatic/alicyclic polyepoxides, and aliphatic/alicyclic polymaleimide urethane compounds obtained by urethanization reaction of aliphatic/alicyclic maleimide alcohol and various aliphatic/alicyclic polyisocyanates.

Specific examples thereof include aliphatic bismaleimide compounds represented by the following general formula (X1) and general formula (X2) obtained by a dehydration esterification reaction or a transesterification reaction of a maleimide alkyl carboxylic acid or maleimide alkyl carboxylic acid ester having an alkyl group having 1 to 6 carbon atoms, more preferably a linear alkyl group, and polyethylene glycol having a number average molecular weight of 100 to 1000 and/or polypropylene glycol having a number average molecular weight of 100 to 1000 and/or polytetramethylene glycol having a number average molecular weight of 100 to 1000.

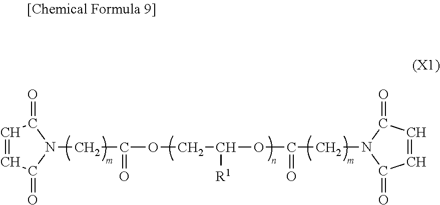

In the above formula, m represents an integer of 1 to 6, n represents a value of 2 to 23, and R₁ represents a hydrogen atom or a methyl group.

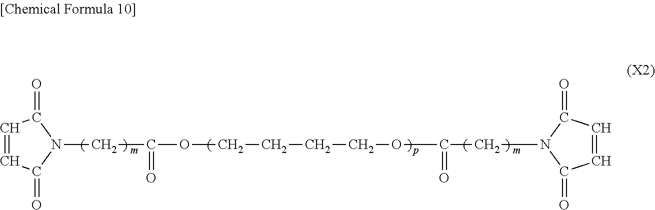

In the above formula, m represents an integer of 1 to 6, and p represents a value of 2 to 14.

<<(4) Polyfunctional Aromatic Maleimide>>

Examples of the polyfunctional aromatic maleimide (4) include N,N′-(4,4′-diphenylmethane)bismaleimide, bis-(3-ethyl-5-methyl-4-maleimidophenyl)methane, 2,2′-bis-(4-(4-maleimidophenoxy)propane, N,N′-(4,4′-diphenyloxy)bismaleimide, N,N′-p-phenylenebismaleimide, N,N′-m-phenylenebismaleimide, N,N′-2,4-tolylene bismaleimide, N,N′-2,6-tolylene bismaleimide, aromatic polymaleimide ester compounds obtained by dehydration esterification of maleimide carboxylic acid and various aromatic polyols or transesterification reaction of maleimide carboxylic acid ester and various aromatic polyols, aromatic polymaleimide ester compounds obtained by ether ring-opening reaction of maleimide carboxylic acid and various aromatic polyepoxides, and aromatic polymaleimide urethane compounds obtained by urethanization reaction of maleimide alcohol and various aromatic polyisocyanates.

Of these, the maleimide compound is preferably polyfunctional. The maleimide compound preferably has a bismaleimide skeleton. The maleimide compound can be used singly, or in combination of two or more.

The weight average molecular weight of the maleimide compound is not particularly limited, and can be 100 or more, 200 or more, 500 or more, 750 or more, 1000 or more, 2000 or more, or 100000 or less, 50000 or less, 10000 or less, 5000 or less, 4000 or less, or 3500 or less.

<<Content of Maleimide Compound>>

The content of the maleimide compound can be typically 0.5 to 50% by mass, 1 to 40% by mass, or 1.5 to 30% by mass, based on the total solid content in the curable composition. In addition, from another point of view, the blending ratio of the predetermined polyphenylene ether and the maleimide compound in the curable composition can be 9:91 to 99:1, 17:83 to: 95:5, or 25:75 to 90:10 as a solid content ratio.

<<Crosslinked Polystyrene-Based Particles>>>

Crosslinked polystyrene-based particles constituting the curable composition of the present invention are polystyrene-based particles obtained by three-dimensionally crosslinking a monomer including a styrene structure. Unlike common polystyrene, the crosslinked polystyrene-based particles do not dissolve in the composition and are dispersed as particles. The curable composition including a combination of the predetermined polyphenylene ether and the cross-linked polystyrene-based particles exhibits low dielectric properties and can further provide a cured film that is excellent in heat resistance, tensile properties, and the like.

The crosslinked polystyrene-based particles constituting the curable composition of the present invention can be produced, for example, by polymerizing a monomer having a styrene structure (styrene-based monomer) and a polyfunctional monomer to synthesize, drying, and classifying crosslinked polystyrene-based particles.

The polymerization method is not particularly limited, and can be performed by a known method. Examples of the polymerization method include bulk polymerization, emulsion polymerization, soap-free emulsion polymerization, seed polymerization, and suspension polymerization. More specifically, when suspension polymerization is used as the polymerization method, the polymerization can be performed by the following method.

A raw material monomer including a styrene-based monomer and a polyfunctional monomer (crosslinkable monomer) is subjected to suspension polymerization in an aqueous medium in the presence of a polymerization initiator to provide a suspension containing crosslinked polystyrene-based particles. The suspension polymerization is performed by dispersing droplets of a mixture (oil phase) including a raw material monomer and a polymerization initiator in an aqueous medium (aqueous phase) to polymerize the raw material monomer.

The styrene-based monomer is not particularly limited, and in addition to styrene, there can be used styrene derivatives such as methylstyrene, ethylstyrene, dimethylstyrene, butylstyrene, propylstyrene, methoxystyrene, phenylstyrene, chlorostyrene, dichlorostyrene, and bromostyrene. The styrene-based monomer may be used singly, or may be used in combination of two or more.

Examples of the polyfunctional monomer include: acryl-based polyfunctional monomers such as trimethylolpropane tri(meth)acrylate, ethylene glycol di(meth)acrylate, diethylene glycol di(meth)acrylate, triethylene glycol di(meth)acrylate, decaethylene glycol di(meth)acrylate, pentadecaethylene glycol di(meth)acrylate, pentacontahectaethylene glycol di(meth)acrylate, pentaerythritol tetra(meth)acrylate, 1,3-butyleneglycol di(meth)acrylate, and allyl (meth)acrylate; and aromatic divinyl compounds such as divinylbenzene, divinylnaphthalene, or derivatives thereof. The polyfunctional monomer may be used singly, or may be used in combination of two or more.

The raw material monomer may include another monomer copolymerizable with a styrene-based monomer or the like.

Additional components, polymerization conditions, and the like during polymerization can be those described in JP 2018-90833 A.

The average particle size of the crosslinked polystyrene-based particles constituting the curable composition of the present invention may be 100 μm or less, 10 m or less, 5 μm or less, and 1 μm or less. It is considered that the smaller average particle size of the crosslinked polystyrene-based particles provides the better tensile properties of the cured product. The average particle size may be, for example, 0.01 m or more, 0.05 μm or more, and 0.1 μm or more. Herein, the average particle size can be determined as a median diameter (d50, volume basis) in a cumulative distribution from a measured value of a particle size distribution by a laser diffraction/scattering method using a commercially available laser diffraction/scattering type particle size distribution measuring apparatus.

The content of the crosslinked polystyrene-based particles constituting the curable composition of the present invention may be 5 parts by mass or more, 10 parts by mass or more, or 20 parts by mass or more, and may be 300 parts by mass or less, 200 parts by mass or less, 150 parts by mass or less, or 100 parts by mass or less, with respect to 100 parts by mass of the polyphenylene ether.

The shape of the crosslinked polystyrene-based particles constituting the curable composition of the present invention is not particularly limited, and is preferably spherical.

The crosslinked polystyrene-based particles constituting the curable composition of the present invention can be produced based on a known method. The crosslinked polystyrene-based particles can be produced, for example, based on the methods disclosed in JP 2004-043557 A, JP 2004-292624 A, JP 2010-254991 A, JP 2012-201825 A, and WO 2013/030977.

In addition, a commercially available product may be used as the crosslinked polystyrene-based particles constituting the curable composition of the present invention. Examples of the commercially available product include SBX series manufactured by SEKISUT CHEMICAL CO., LTD.

<<<Reactive Styrene Copolymer>>>

In order to improve tensile properties and the like, the curable composition preferably contains a predetermined polyphenylene ether having a hydroxyl group and a reactive styrene copolymer. When used in combination with the reactive styrene copolymer, the predetermined polyphenylene ether may not include an unsaturated carbon bond.

The reactive styrene copolymer has a functional group (hydroxyl group-reactive functional group) capable of reacting with a hydroxyl group of a predetermined polyphenylene ether in the structure. The reactive styrene copolymer preferably has two or more of hydroxyl group-reactive functional groups.

Examples of the hydroxyl group-reactive functional group include a cyclic (thio)ether group, an isocyanate group, an oxazoline group, and an acid anhydride group. The reactive styrene copolymer can be obtained by copolymerizing styrene with a monomer other than styrene containing a hydroxyl group-reactive functional group.

The monomer other than styrene containing a hydroxyl group-reactive functional group is not particularly limited as long as it contains a hydroxyl group-reactive functional group and is copolymerizable with styrene, and examples thereof include maleic anhydride and oxazoline.

A monomer containing no hydroxyl group-reactive functional group (for example, butadiene) may be included as the monomer other than styrene.

The reactive styrene copolymer can be produced by copolymerizing the above monomer according to a conventionally known method.

The reactive styrene copolymer may be hydrogenated.

The reactive styrene copolymer may be any of a random copolymer, a block copolymer, and the like.

The number average molecular weight or weight average molecular weight of the reactive styrene copolymer is preferably 1000 to 3000000, and more preferably 10000 to 2000000.

The reactive styrene copolymer can be contained in the curable composition such that the ratio (A/B) of the equivalent A of the hydroxyl group in the predetermined polyphenylene ether to the equivalent B of the reactive functional group in the reactive styrene copolymer is preferably 0.1 to 10, more preferably 0.2 to 8, and particularly preferably 0.5 to 5.

A cured product obtained by curing a curable composition including a reactive styrene copolymer together with a predetermined polyphenylene ether can improve adhesion and tensile strength while maintaining a low dielectric constant derived from the predetermined polyphenylene ether.

<<<Other Components>>>

The other components may include known components, for example, components such as a crosslinkable curing agent, a filler component, a peroxide, a flame retardancy improver (phosphorus-based compound), an elastomer, a cellulose nanofiber, a cyanate ester resin, an epoxy resin, a phenol-novolac resin, a dispersant, a thermosetting catalyst, and an adhesion imparting agent. These may be used singly, or may be used in combination of two or more.

<<Crosslinkable Curing Agent>>

When the predetermined polyphenylene ether has an unsaturated carbon bond, the curable composition of the present invention preferably includes a crosslinkable curing agent.

The crosslinkable curing agent having good compatibility with polyphenylene ether is used, and there are preferable polyfunctional vinyl compounds such as divinylbenzene, divinylnaphthalene, and divinylbiphenyl; a vinyl benzyl ether-based compound synthesized from reaction of phenol and vinyl benzyl chloride; an allyl ether-based compound synthesized from reaction of styrene monomer, phenol, and allyl chloride; and trialkenyl isocyanurate. Trialkenyl isocyanurate having particularly good compatibility with a polyphenylene ether is preferable as the crosslinkable curing agent, and particularly, triallyl isocyanurate (hereinafter, TAIC (registered trademark)) and triallyl cyanurate (hereinafter, TAC) are preferable. These exhibit low dielectric properties and can enhance heat resistance. TAIC (registered trademark) is particularly preferable because of excellent compatibility with polyphenylene ether.

In addition, a (meth)acrylate compound (a methacrylate compound and an acrylate compound) may be used as the crosslinkable curing agent. Particularly, it is preferable to use a 3 to 5 functional (meth)acrylate compound. Trimethylolpropane trimethacrylate or the like can be used as the 3 to 5 functional methacrylate compound, and whereas, trimethylolpropane triacrylate or the like can be used as the 3 to 5 functional acrylate compound. Using these crosslinkable curing agents can enhance heat resistance. The crosslinkable curing agent may be used singly, or may be used in combination of two or more.

When the curable composition including the predetermined polyphenylene ether of the present invention includes a hydrocarbon group having an unsaturated carbon bond, a cured product excellent in dielectric properties can be obtained particularly by curing the curable composition with a crosslinkable curing agent.

The blending ratio of the predetermined polyphenylene ether and the crosslinkable curing agent (for example, trialkenyl isocyanurate) in the curable composition of the present invention is preferably 20:80 to 90:10, and more preferably 30:70 to 90:10 as the solid content ratio (predetermined polyphenylene ether:crosslinkable curing agent). Within such a range, a cured product excellent in low dielectric properties and heat resistance is obtained.

The content of the solvent in the curable composition is not particularly limited, and can be appropriately adjusted according to the use of the curable composition.

<<Filler Component>>

The curable composition of the present invention includes a known filler component in addition to the crosslinked polystyrene-based particles, thereby further allowing adjusting properties such as film formability of the composition, thermal dimensional stability of the cured product, thermal conductivity, imparting of flame retardancy, dielectric constant, and dielectric loss tangent.

Examples of the filler component include inorganic fillers and organic fillers.

Examples of the inorganic filler include metal oxides such as silica, alumina, and titanium oxide; metal hydroxides such as aluminum hydroxide and magnesium hydroxide; clay minerals such as tale and mica; filler having a perovskite-type crystal structure such as barium titanate or strontium titanate; boron nitride, aluminum borate, barium sulfate, and calcium carbonate.

Examples of the organic filler include fluororesin fillers such as polytetrafluoroethylene (PTFE), a tetrafluoroethylene/ethylene copolymer (ETFE), a tetrafluoroethylene/perfluoroalkyl vinyl ether copolymer (PFA), a tetrafluoroethylene/hexafluoropropylene copolymer (FEP), polychlorotrifluoroethylene (PCTFE), polyvinylidene fluoride (PVDF), and polyvinyl fluoride (PVF); and hydrocarbon-based resin fillers such as cycloolefin polymer (COP) and cycloolefin copolymer (COC).

<Silica>

Of the inorganic fillers described above, silica can improve the film formability of the composition, impart flame retardancy to the cured product, and further, can achieve a low dielectric loss tangent and a low thermal expansion at a high level.

The average particle size of silica is preferably 0.02 to 10 μm, and more preferably 0.02 to 3 μm. Herein, the average particle size can be determined as a median diameter (d50, volume basis) in a cumulative distribution from a measured value of a particle size distribution by a laser diffraction/scattering method using a commercially available laser diffraction/scattering type particle size distribution measuring apparatus.

Silicas having different average particle sizes can also be used in combination. From the viewpoint of achieving high silica filling, for example, minute silica of nano order having an average particle size of less than 1 μm may be used in combination with silica having an average particle size of 1 μm or more.

The silica may be surface-treated with a coupling agent. Treating the surface with a silane coupling agent can improve dispersibility with the polyphenylene ether. In addition, the affinity with an organic solvent can be improved.

For example, an epoxysilane coupling agent, a mercaptosilane coupling agent, and a vinylsilane coupling agent can be used as the silane coupling agent. For example, 7-glycidoxypropyltrimethoxysilane and γ-glycidoxypropylmethyldimethoxysilane can be used as the epoxysilane coupling agent. For example, γ-mercaptopropyltriethoxysilane can be used as the mercaptosilane coupling agent. For example, vinyltriethoxysilane can be used as the vinylsilane coupling agent.

The amount of the silane coupling agent used may be, for example, 0.1 to 5 parts by mass or 0.5 to 3 parts by mass with respect to 100 parts by mass of silica.

The content of the filler component such as silica may be 50 to 400 parts by mass or 100 to 400 parts by mass with respect to 100 parts by mass of the polyphenylene ether. Alternatively, the content of the filler component such as silica may be 10 to 30% by mass based on the total solid content of the composition.

In addition, from another viewpoint, the blending amount of the filler component such as silica may be 100 to 700 parts by mass or 200 to 600 parts by mass with respect to 100 parts by mass of the polyphenylene ether. Alternatively, the content of the filler component such as silica may be 10 to 90% by mass based on the total solid content of the composition.

<<Peroxide>>

When the predetermined polyphenylene ether has an unsaturated carbon bond, the curable composition of the present invention preferably includes a peroxide.

Examples of the peroxide include methyl ethyl ketone peroxide, methyl acetoacetate peroxide, acetylacetoperoxide, 1,1-bis(t-butylperoxy)cyclohexane, 2,2-bis(t-butylperoxy) butane, t-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, di-t-butyl hydroperoxide, t-butyl hydroperoxide, dicumyl peroxide, 2,5-dimethyl-2,5-di(t-butylperoxy) hexane, 2,5-dimethyl-2,5-di(t-butylperoxy) hexyne, 2,5-dimethyl-2,5-di(t-butylperoxy)-3-butene, acetyl peroxide, octanoyl peroxide, lauroyl peroxide, benzoyl peroxide, m-toluyl peroxide, diisopropylperoxydicarbonate, t-butylene peroxybenzoate, di-t-butyl peroxide, t-butylperoxyisopropyl monocarbonate, and α,α′-bis(t-butylperoxy-m-isopropyl) benzene. The peroxide may be used singly, or may be used in combination of two or more.

Of these, the peroxide having a 1-minute half-life temperature of 130° C. to 180° C. is desirable from the viewpoint of ease of handling and reactivity. Such a peroxide has a relatively high reaction starting temperature, and therefore it is difficult to promote curing when curing is not required, such as during drying, and the preservability of the polyphenylene ether resin composition is not deteriorated and the volatility is low, whereby the peroxide does not volatilize during drying or storage, leading to good stability.

The amount of the peroxide added is preferably 0.01 to 20 parts by mass, more preferably 0.05 to 10 parts by mass, and particularly preferably 0.1 to 10 parts by mass with respect to 100 parts by mass of the solid content of the curable composition in terms of the total amount of the peroxide. Setting the total amount of the peroxides within this range can prevent deterioration of the film quality when the coating film is formed while making the effect at low temperature sufficient.

In addition, a radical initiator, e.g., an azo compound such as azobisisobutyronitrile or azobisisovaleronitrile, dicumyl, or 2,3-diphenylbutane may be contained as necessary.

<<Phosphorus-Based Compound>>

The curable composition may include a phosphorus-based compound. Examples of the phosphorus-based compound preferable in the present invention include a phosphorus-containing flame retardant and a predetermined phosphorus compound depending on the functions and properties (purpose of blending) thereof. The phosphorus-containing flame retardant and the predetermined phosphorus compound are specified by the functions and properties thereof, and therefore one phosphorus-based compound may correspond to both or only one of the predetermined phosphorus compound and the phosphorus-containing flame retardant.

<Phosphorus-Containing Flame Retardant>

The curable composition may include a phosphorus-containing flame retardant. Blending the phosphorus-containing flame retardant in the composition can improve the self-extinguishing property of a cured product obtained by curing the composition.

Examples of the phosphorus-containing flame retardant include phosphoric acid or an ester thereof, and phosphorous acid or an ester thereof. Alternatively, example thereof includes a condensate thereof.

The phosphorus-containing flame retardant is preferably used in combination with silica. Therefore, the phosphorus-containing flame retardant is preferably compatible with the polyphenylene ether from the viewpoint of high silica filling. Whereas, there is also a concern that the phosphorus-containing flame retardant bleeds out.

In a preferable embodiment for eliminating the concern of bleed-out, the phosphorus-containing flame retardant has one or more unsaturated carbon bonds in the molecular structure. The phosphorus-containing flame retardant having an unsaturated carbon bond can be integrated by reacting with the unsaturated carbon bond of the polyphenylene ether when the composition is cured. This eliminates the concern of bleeding out of the phosphorus-containing flame retardant.

A preferable phosphorus-containing flame retardant has a plurality of unsaturated carbon bonds in the molecular structure of the phosphorus-containing flame retardant. The phosphorus-containing flame retardant having a plurality of unsaturated carbon bonds can also function as a crosslinkable curing agent described later. From the viewpoint of contributing to crosslinking of the polyphenylene ether, the phosphorus-containing flame retardant having a plurality of unsaturated carbon bonds can also be expressed as a phosphorus-containing crosslinkable curing agent or a phosphorus-containing crosslinking aid.

The phosphoric acid or an ester thereof is a compound represented by the following formula (6).

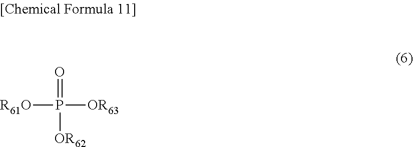

In the formula (6), R₆₁ to R₆₃ each independently represent a hydrogen atom or a hydrocarbon group having 1 to 15 (preferably 1 to 12) carbon atoms. The hydrocarbon group may have an unsaturated carbon bond. In addition, the hydrocarbon group may include one or more heteroatoms such as oxygen, nitrogen, and sulfur. However, these heteroatoms included are problematic in that the polarity increases and the dielectric properties are adversely affected, and thus the hydrocarbon group preferably includes no heteroatom. Typical examples of such a hydrocarbon group include a methyl group, an ethyl group, an octyl group, a phenyl group, a cresyl group, a butoxyethyl group, a vinyl group, an allyl group, an acryloyl group, and a methacryloyl group.

Examples of the phosphoric acid ester include trimethyl phosphate, triethyl phosphate, tributyl phosphate, trioctyl phosphate, tributoxyethyl phosphate, triphenyl phosphate, tricresyl phosphate, cresyl diphenyl phosphate, octyl diphenyl phosphate, tri(2-ethylhexyl) phosphate, diisopropylphenyl phosphate, trixylenyl phosphate, tris(isopropylphenyl) phosphate, trinaphthyl phosphate, bisphenol A bisphosphate, hydroquinone bisphosphate, resorcin bisphosphate, resorcinol bis-diphenyl phosphate, and trioxybenzene triphosphate.

Examples of the phosphate ester having an unsaturated carbon bond in the molecular structure include trivinyl phosphate, triallyl phosphate, triacryloyl phosphate, trimethacryloyl phosphate, trisacryloyloxyethyl phosphate, and trismethacryloyloxyethyl phosphate.

The phosphorous acid or an ester thereof is a compound represented by the following formula (7).

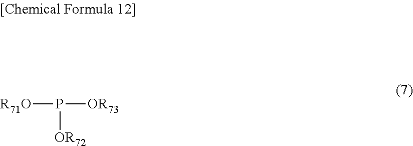

R₇₁ to R₇₃ in formula (7) are applied to the description of R₆₁ to R₆₃ in formula (6).

Examples of the phosphite ester include trimethyl phosphite, triethyl phosphite, tributyl phosphite, trioctyl phosphite, tributoxyethyl phosphite, triphenyl phosphite, tricresyl phosphite, cresyl diphenyl phosphite, octyl diphenyl phosphite, tri(2-ethylhexyl) phosphite, diisopropylphenyl phosphite, trixylenyl phosphite, tris(isopropylphenyl) phosphite, trinaphthyl phosphite, bisphenol A bisphosphite, hydroquinone bisphosphite, resorcin bisphosphite, resorcinol-diphenyl phosphite, and trioxybenzene triphosphite.

Examples of the phosphite ester having an unsaturated carbon bond in the molecular structure include trivinyl phosphite, triallyl phosphite, triacryloyl phosphite, and trimethacryloyl phosphite.

The content of the phosphorus-containing flame retardant may be 1 to 5% by mass as the phosphorus amount based on the total solid content of the composition. Within the above range, the self-extinguishing property, heat resistance, and dielectric properties of the cured product obtained by curing the composition can be achieved at a high level in a well-balanced manner.

<Predetermined Phosphorus Compound>

The curable composition containing a predetermined phosphorus compound can efficiently improve the flame retardancy of a cured product obtained by curing the composition.

The predetermined phosphorus compound is a compound including one or more phosphorus elements in the molecular structure, and means a compound having a property of being incompatible with the above branched polyphenylene ether.

Examples of the phosphorus compound include a phosphoric acid ester compound, a phosphinic acid compound, and a phosphorus-containing phenol compound.

The phosphoric acid ester compound is a compound represented by the following formula (6).

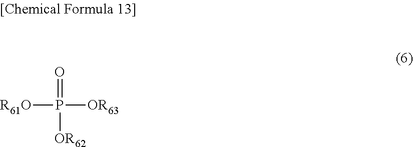

In the formula (6), R₆₁ to R₆₃ each independently represent a hydrogen atom, a linear or branched saturated or unsaturated hydrocarbon group having 1 to 15 (preferably 1 to 12) carbon atoms. The hydrocarbon group is preferably an alkyl group, an alkenyl group, an unsubstituted aryl group, or an aryl group having an alkyl group or an alkenyl group as a substituent. Typical examples of such a hydrocarbon group include a methyl group, an ethyl group, an octyl group, a vinyl group, an allyl group, a phenyl group, a benzyl group, a tolyl group, and a vinylphenyl group.

Examples of the phosphoric acid ester compound include trimethyl phosphate, triethyl phosphate, triphenyl phosphate, tricresyl phosphate, trixylenyl phosphate, bisphenol A bisdiphenyl phosphate, resorcinol bis-diphenyl phosphate, 1,3-phenylene-tetrakis (2,6-dimethylphenyl phosphate), 1,4-phenylene-tetrakis (2,6-dimethylphenyl phosphate), and 4,4′-biphenylene-tetrakis (2,6-dimethylphenyl phosphate).

A phosphinic acid metal salt compound represented by the following formula (8) is preferable as the phosphinic acid compound.

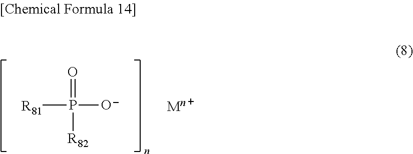

In the formula (8), R₈₁ and R₈₂ are independently a hydrogen atom or a linear or branched, saturated or unsaturated hydrocarbon group. The hydrocarbon group is preferably a linear or branched alkyl group having 1 to 6 carbon atoms, a linear or branched alkenyl group having 1 to 6 carbon atoms, a cycloalkyl group having 3 to 6 carbon atoms, a phenyl group, a benzyl group, or a tolyl group. The hydrocarbon group is particularly preferably an alkyl group having 1 to 4 carbon atoms.

In the formula (8), M represents an n-valent metal ion. The metal ion M is an ion of at least one metal selected from the group consisting of Mg, Ca, Al, Sb, Sn, Ge, Ti, Fe, Zr, Ce, Bi, Sr, Mn, Li, Na, and K, and at least a part thereof is preferably an Al ion.

Examples of the phosphinic acid metal salt compound include aluminum diethylphosphinate.

The phosphinic acid metal salt compound may be surface-treated with a coupling agent so as to have an organic group. Treating the surface with a silane coupling agent can also improve affinity with an organic solvent. In addition, having an unsaturated carbon bond such as a vinyl group or a cyclic ether bond such as an epoxy group can lead to crosslinking with other components during curing, resulting in improvement of heat resistance and prevention of bleeding out.

For example, an epoxysilane coupling agent, a mercaptosilane coupling agent, and a vinylsilane coupling agent can be used as the silane coupling agent. For example, γ-glycidoxypropyltrimethoxysilane and γ-glycidoxypropylmethyldimethoxysilane can be used as the epoxysilane coupling agent. For example, γ-mercaptopropyltriethoxysilane can be used as the mercaptosilane coupling agent. For example, vinyltriethoxysilane can be used as the vinylsilane coupling agent.

Examples of the phosphorus-containing phenol compound include diphenylphosphinylhydroquinone, diphenylphosphenyl-1,4-dioxinaphthaline, 1,4-cyclooctylenephosphinyl-1,4-phenyldiol, and 1,5-cyclooctylenephosphinyl-1,4-phenyldiol.

A phosphinic acid metal salt compound having no compatibility with the branched polyphenylene ether is particularly preferable as the predetermined phosphorus compound, because the phosphorus content per molecule is high.

In the present invention, whether or not the phosphorus compound is compatible with the branched polyphenylene ether is determined based on the following test.

The branched polyphenylene ether is typically soluble in cyclohexanone. That is, when the phosphorus compound is also soluble in cyclohexanone, it can be said that the mixture of the branched polyphenylene ether and the phosphorus compound is uniformly compatible. Based on this, whether or not the phosphorus compound is compatible with the branched polyphenylene ether is determined by confirming the solubility of the phosphorus compound in cyclohexanone.

Specifically, 10 g of a phosphorus compound and 100 g of cyclohexanone are put in a 200 mL sample bottle, a stirring bar is put therein, and the mixture is stirred at 25° C. for 10 minutes and then left at 25° C. for 10 minutes. The phosphorus compound having a solubility of less than 0.1 (10 g/100 g) is determined to be incompatible with the branched polyphenylene ether, and the phosphorus compound having a solubility of 0.1 (10 g/100 g) or more is determined to be compatible with the branched polyphenylene ether.

The above solubility of the phosphorus compound may be less than 0.08 (8 g/100 g) or less than 0.06 (6 g/100 g).

When the branched polyphenylene ether and the flame retardant compatible with the branched polyphenylene ether are used in combination, the branched polyphenylene ether and the flame retardant are excessively compatible with each other, and this result has caused the problem of the deteriorated heat resistance of the resulting cured product in some cases. Such a problem can be solved by using a flame retardant incompatible with the branched polyphenylene ether.

The content of the phosphorus compound may be 1 to 10% by mass, 2 to 8% by mass, or 3 to 6% by mass based on the total solid content of the composition. Within the above range, the flame retardancy, heat resistance, and dielectric properties of the cured product obtained by curing the composition can be achieved at a high level in a well-balanced manner.

<<Elastomer>>

The curable composition may include an elastomer. Including an elastomer improves film formability. The effect of improving tensile strength and adhesion is superior to a conventional combination of a polyphenylene ether (unbranched polyphenylene ether) and an elastomer. This is considered to be excellent compatibility of the branched polyphenylene ether and the elastomer, allowing providing a uniform cured film.

The elastomer preferably has sufficient compatibility with a predetermined polyphenylene ether or a side-chain epoxidized polyphenylene ether.

The elastomer is roughly classified into a thermosetting elastomer and a thermoplastic elastomer. Any of them can be used because of improving the film formability, and a thermoplastic elastomer is more preferable because the tensile properties of the cured product can be improved.

The curable composition preferably includes a thermoplastic elastomer. Blending the thermoplastic elastomer in the composition can improve the tensile properties of the cured product. The cured product of the polyphenylene ether used in the present invention has a low elongation at break and tends to be brittle in some cases; however, using a thermoplastic elastomer in combination can improve the elongation at break while maintaining dielectric properties. The thermoplastic elastomer is preferably used in combination with silica.

Examples of the thermosetting elastomer include: diene-based synthetic rubbers such as polyisoprene rubber, polybutadiene rubber, styrene-butadiene rubber, polychloroprene rubber, nitrile rubber, and ethylene-propylene rubber; non-diene-based synthetic rubbers such as ethylene-propylene rubber, butyl rubber, acrylic rubber, polyurethane rubber, fluororubber, silicone rubber, and epichlorohydrin rubber; and natural rubber.

Examples of the thermoplastic elastomer include a styrene-based elastomer, an olefin-based elastomer, a urethane-based elastomer, a polyester-based elastomer, a polyamide-based elastomer, an acrylic-based elastomer, and a silicone-based elastomer. From the viewpoint of high compatibility with the polyphenylene ether and high dielectric properties, it is particularly preferable that at least a part of the elastomer is a styrene-based elastomer.

The content ratio of the styrene-based elastomer in 100% by mass of the elastomer may be, for example, 10% by mass or more, 20% by mass or more, 30% by mass or more, 40% by mass or more, 50% by mass or more, 60% by mass or more, 70% by mass or more, 80% by mass or more, 90% by mass or more, 95% by mass or more, or 100% by mass.

Examples of the styrene-based elastomer include: styrene-butadiene copolymer such as styrene-butadiene-styrene block copolymer; styrene-isoprene copolymer such as styrene-isoprene-styrene block copolymer; styrene-ethylene-butylene-styrene block copolymer, and styrene-ethylene-propylene-styrene block copolymer. In addition, examples thereof include hydrogenated products of these copolymers. A styrene-based elastomer having no unsaturated carbon bond, such as styrene-ethylene-butylene-styrene block copolymer, is preferable because the obtained cured product has particularly good dielectric properties.

The content ratio of the styrene block in the styrene-based elastomer is preferably 20 to 70 mol %. Alternatively, the content ratio of the styrene block in the styrene-based elastomer is preferably 10 to 70% by mass, 30 to 60% by mass, or 40 to 50% by mass. The content ratio of the styrene block can be determined from the integral ratio of the spectrum measured by 1H-NMR.

Herein, the raw material monomers of the styrene-based elastomer include not only styrene but also styrene derivatives such as (t-methylstyrene, 3-methylstyrene, 4-propylstyrene, and 4-cyclohexylstyrene.

The weight average molecular weight of the elastomer may be 1000 to 300000 or 2000 to 150000. The weight average molecular weight is the lower limit value or more, providing excellent low thermal expansion properties, and the weight average molecular weight is the upper limit value or less, providing excellent compatibility with other components.

Particularly, the weight average molecular weight of the thermoplastic elastomer may be 1000 to 300000 or 2000 to 150000. The weight average molecular weight is the lower limit value or more, providing excellent low thermal expansion properties, and the weight average molecular weight is the upper limit value or less, providing excellent compatibility with other components.

The weight average molecular weight of the elastomer is measured by GPC and converted by a calibration curve prepared with using standard polystyrene.

The blending amount of the elastomer may be 50 to 200 parts by mass with respect to 100 parts by mass of the polyphenylene ether. In other words, the blending amount of the elastomer may be 30 to 70% by mass based on the total solid content of the composition. Within the above range, good curability, moldability, and chemical resistance can be achieved in a well-balanced manner.

Particularly, the blending amount of the thermoplastic elastomer may be 30 to 100 parts by mass with respect to 100 parts by mass of the polyphenylene ether. In other words, the blending amount of the thermoplastic elastomer may be 3 to 20% by mass based on the total solid content of the composition. Within the above range, good curability, moldability, and chemical resistance can be achieved in a well-balanced manner.

The elastomer may have a functional group (including a bond) that reacts with other components.

<<Solvent>>

The curable composition is typically provided or used in a state in which the polyphenylene ether is dissolved in a solvent. The polyphenylene ether of the present invention has higher solubility in a solvent than conventional polyphenylene ethers, and therefore the selection of solvents to be used can be widened depending on the application of the curable composition.

Examples of the solvent that can be used in the curable composition of the present invention include solvents having relatively high safety, such as N-methyl-2-pyrrolidone (NMP), tetrahydrofuran (THF), cyclohexanone, propylene glycol monomethyl ether acetate (PMA), diethylene glycol monoethyl ether acetate (CA), methyl ethyl ketone, and ethyl acetate, in addition to conventionally usable solvents such as chloroform, methylene chloride, and toluene. The solvent may be N,N-dimethylformamide (DMF). The solvent may be used singly, or may be used in combination of two or more.

The content of the solvent in the curable composition is not particularly limited, and can be appropriately adjusted according to the use of the curable composition.

<<<<Dry Film and Prepreg>>>>

The dry film or prepreg of the present invention is obtained by applying the above curable composition onto a base material or impregnating the base material with the above curable composition.

Here, examples of the base material include metal foils such as copper foils, films such as polyimide film, polyester film, and polyethylene naphthalate (PEN) film, and fibers such as glass cloth and aramid fiber.

The dry film is obtained by, for example, applying and drying a curable composition on a polyethylene terephthalate film, and laminating a polypropylene film as necessary.

The prepreg is obtained by, for example, impregnating glass cloth with a curable composition and drying the glass cloth.

<<<<Cured Product>>>>

The cured product of the present invention is obtained by curing the above curable composition.

The method for obtaining a cured product from the curable composition is not particularly limited, and can be appropriately changed according to the composition of the curable composition. For an example, the step of applying a curable composition onto a base material (for example, applying by an applicator or the like) is performed, then a drying step of drying the curable composition is performed as necessary, and a thermal curing step of thermally crosslinking the polyphenylene ether by heating (for example, heating by an inert gas oven, a hot plate, a vacuum oven, a vacuum press machine, or the like) may be performed. The conditions for performing each step (for example, coating thickness, drying temperature and time, heating temperature and time, and the like) may be appropriately changed according to the composition or use of the curable composition.

<<<<Laminated Board>>>>

In the present invention, a laminated board can be produced by using the above prepreg.

For example, one sheet or a plurality of sheets of the prepreg of the present invention are laminated, a metal foil such as a copper foil is further laminated on both upper and lower surfaces or one surface of the prepreg, and this laminated body is subjected to heat-and-pressure molding, thereby allowing producing a laminated board having the metal foil on both surfaces or the metal foil on one surface of the laminated and integrated body.

<<<<Electronic Component>>>>

The above cured product has excellent dielectric properties and heat resistance, and thus can be used for electronic components and the like.

The electronic component having such a cured product of the present invention is not particularly limited, and preferable examples thereof include large-capacity high-speed communication typified by a fifth generation communication system (5G) and a millimeter wave radar for an advanced driving system (ADAS) of an automobile.

<<<<Detailed Form of the Present Invention>>>>

Herein, the present invention may be the following inventions (I) to (IV).

<<<Invention (I)>>>

The present invention (I-1) is a curable composition including:
a polyphenylene ether having a functional group including an unsaturated carbon bond, the polyphenylene ether being obtained from raw material phenols including phenols satisfying at least condition 1, and having less than 0.6 of a slope calculated by a conformation plot; and

a compound containing at least one maleimide group in one molecule.

The above curable composition may include trialkenyl isocyanurate.

The present invention (I-2) is a dry film or a prepreg obtained by applying the curable composition of the invention (I-1) onto a base material.

The present invention (I-3) is a cured product obtained by curing the curable composition of the invention (I-1).

The present invention (I-4) is a laminated board including a cured product of the invention (I-3).

The present invention (I-5) is an electronic component including the cured product of the invention (I-3).

The present invention (I) can provide a curable composition that is soluble in various solvents (organic solvents other than highly toxic organic solvents, for example, cyclohexanone) while maintaining low dielectric properties, wherein a film obtained by curing has excellent mechanical strength and low linear expansivity.

<<<Invention (II)>>>

The present invention (II-1) is a curable composition including:

a polyphenylene ether having a functional group including an unsaturated carbon bond, the polyphenylene ether being obtained from raw material phenols including phenols satisfying at least condition 1, and having less than 0.6 of a slope calculated by a conformation plot; and

a triazine-based compound containing at least one thiol group.

The above curable composition may include trialkenyl isocyanurate.

The present invention (II-2) is a dry film or a prepreg obtained by applying the curable composition of the invention (II-1) onto a base material.

The present invention (II-3) is a cured product obtained by curing the curable composition of the invention (II-1).

The present invention (II-4) is a laminated board including a cured product of the invention (II-3).

The present invention (II-5) is an electronic component including the cured product of the invention (II-3).

The present invention (II) can provide a curable composition that is soluble in various solvents (organic solvents other than highly toxic organic solvents, for example, cyclohexanone) while maintaining low dielectric properties, wherein a film obtained by curing has mechanical strength (for example, elongation) and peel strength.

<<<Invention (III)>>>

The present invention (III-1) is a curable composition including:

a polyphenylene ether having a so-called branched structure and a hydroxyl group, the polyphenylene ether obtained from raw material phenols including phenols satisfying at least condition 1, and having a less than 0.6 of a slope calculated by a conformation plot; and

a styrene copolymer having a functional group capable of reacting with the hydroxyl group.

The present invention (III-2) is the curable composition of the present invention (III-1), wherein the polyphenylene ether further has a functional group including an unsaturated carbon bond.

The present invention (III-3) is a dry film or a prepreg obtained by applying the curable composition of the invention (III-1) or (III-2) onto a base material or impregnating the substrate with the curable composition of the invention (III-1) or (III-2).

The present invention (III-4) is a cured product obtained by curing the curable composition of the invention (III-1) or (III-2).

The present invention (III-5) is a laminated board including a cured product of the invention (III-4).

The present invention (III-6) is an electronic component including the cured product of the invention (III-4).

The present invention (III) can provide a curable composition that is soluble in various solvents (organic solvents other than highly toxic organic solvents, for example, cyclohexanone) while maintaining excellent low dielectric properties, wherein a film obtained by curing has excellent tensile properties and the like.

<<<Invention (IV)>>>

The present invention (IV-1) is a curable composition including:

a polyphenylene ether obtained from raw material phenols including phenols satisfying at least condition 1, and having less than 0.6 of a slope calculated by a conformation plot; and

crosslinked polystyrene-based particles.

The present invention (IV-2) is the curable composition of the present invention (IV-1), wherein the polyphenylene ether further has a functional group including an unsaturated carbon bond.

The present invention (IV-3) is a dry film or a prepreg obtained by applying the curable composition of the invention (IV-1) or (IV-2) onto a base material or impregnating the substrate with the curable composition of the invention (IV-1) or (IV-2).

The present invention (IV-4) is a cured product obtained by curing the curable composition of the invention (IV-1) or (IV-2).

The present invention (IV-5) is a laminated board including a cured product of the invention (IV-4).

The present invention (IV-6) is an electronic component including the cured product of the invention (IV-4).

The present invention (IV) can provide a curable composition that is soluble in various solvents (organic solvents other than highly toxic organic solvents, for example, cyclohexanone) while maintaining excellent low dielectric properties, wherein a film obtained by curing has excellent heat resistance and tensile strength.

### EXAMPLES

Then, the present invention will be described in detail with reference to examples and comparative examples; however, the present invention is not limited thereto at all.

Hereinafter, the curable composition is classified into a plurality of forms (examples I to IV) based on the type of raw material phenols to be used, the type of components included in the curable composition, and the like, and each of the forms will be described.

The number of each of the products (examples, comparative examples, reference examples, evaluation samples, and the like) described in each of the embodiments (example I to example IV) is the independent number in each of the embodiments. Therefore, although the product number in one form and the product number in another form are the same, they do not indicate the same product. In consideration of this point, it is also possible to read a product number described in a certain form (example I to example IV) as a number to which numbers (I to IV) corresponding to the certain form are additionally assigned. For example, products described as “Example 1”, “Case 1”, and “PPE-1” in Example I can be read as “Example I-1”, “Case I-1”, and “PPE-I-1”, respectively.

In the following examples, calculation of the slope of the conformation plot was performed in accordance with the analysis procedure and measurement conditions with the MALS detector described above.

### Example I

<<<Production of Composition>>>

Hereinafter, the production procedure of each composition (compositions of examples 1 to 8 and comparative examples 1 to 3) will be described.

<<Synthesis of PPE Resin>>

<Branched PPE Resin-1 (Thermosetting Side Chain Type): Method 1>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied at 10 ml/min. A raw material solution was prepared by dissolving 105 g of 2,6-dimethylphenol and 13 g of 2-allylphenol, which are raw material phenols, in 1.5 L of toluene. This raw material solution was added dropwise to the flask and reacted at 40° C. for 6 hours while being stirred at a rotation speed of 600 rpm. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin-1.

The branched PPE resin-1 had a number average molecular weight of 20000 and a weight average molecular weight of 60000.

The slope of the conformation plot for the branched PPE resin-1 was 0.31.

<Branched PPE Resin-2 (Thermosetting End Type): Method 2>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied at 10 ml/min. A raw material solution was prepared by dissolving 105 g of 2,6-dimethylphenol and 4.89 g of orthocresol, which are raw material phenols, in 1.5 L of toluene. This raw material solution was added dropwise to the flask and reacted at 40° C. for 6 hours while being stirred at a rotation speed of 600 rpm. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin.

To a 1 L two-necked recovery flask equipped with a dropping funnel, 50 g of the branched PPE resin, 4.8 g of allyl bromide as a modifying compound, and 300 mL of NMP were added and stirred at 60° C. 5 mL of a 5 M aqueous NaOH solution was added dropwise to the solution. Thereafter, stirring was further performed at 60° C. for 5 hours. Then, the reaction solution was neutralized with hydrochloric acid, then reprecipitation was performed in 5 L of methanol, filtration was performed, washing was performed 3 times with a mixed solution of methanol and water in a mass ratio of 80:20, and then drying was performed at 80° C. for 24 hours to obtain a branched PPE resin-2.

The branched PPE resin-2 had a number average molecular weight of 19000 and a weight average molecular weight of 66500.

The slope of the conformation plot for the branched PPE resin-2 was 0.33.

<Unbranched PPE Resin A>

An unbranched PPE resin A was obtained based on the same synthesis method as that for the branched PPE resin-1, except that 34 mL of water was added to a raw material solution in which 7.6 g of 2-allyl-6-methylphenol and 34 g of 2,6-dimethylphenol, which are raw material phenols, were dissolved in 0.23 L of toluene.

The unbranched PPE resin A was insoluble in cyclohexanone and was soluble in chloroform.

The unbranched PPE resin A had a number average molecular weight of 1000 and a weight average molecular weight of 2000.

The slope of the conformation plot of the unbranched PPE resin A was unmeasurable.

<Unbranched PPE Resin B>

An unbranched PPE resin B was obtained based on the same synthesis method as that for the branched PPE resin-1, except for using a raw material solution obtained by dissolving 13.8 g of 2-allyl-6-methylphenol and 103 g of 2,6-dimethylphenol, which are raw material phenols, in 0.38 L of toluene.

The unbranched PPE resin B had a number average molecular weight of 19000 and a weight average molecular weight of 39900.

The slope of the conformation plot for the unbranched PPE resin B was 0.61.

The number average molecular weight (Mn) and weight average molecular weight (Mw) of each PPE resin were determined by gel permeation chromatography (GPC). In GPC, Shodex K-805L was used as a column, the column temperature was 40° C., the flow rate was 1 mL/min, the eluent was chloroform, and the standard material was polystyrene.

<Solvent Solubility of PPE Resin>

Solvent solubility of each PPE resin was confirmed.

The branched PPE resins-1 and 2 were soluble in cyclohexanone.

The unbranched PPE resins A and B were insoluble in cyclohexanone and were soluble in chloroform.

<<Preparation of Resin Composition>>

The varnish of the resin composition according to each of examples and each of comparative examples was obtained as follows.

### Example 1

To 17.4 parts by mass of a branched PPE-1 resin and 5.7 parts by mass of a styrene elastomer (Asahi Kasei Corporation: trade name “H1051”), 60 parts by mass of cyclohexanone as a solvent was added, mixed at 40° C. for 30 minutes, and stirred to complete dissolution.

To the PPE resin solution obtained in this manner, 11.6 parts by mass of TAIC (manufactured by Mitsubishi Chemical Corporation) as a crosslinkable curing agent, 94.4 parts by mass of spherical silica (manufactured by Admatechs Co., Ltd.: trade name “SC2500-SVJ”), 11.1 parts by mass of OP935 (manufactured by Clariant Chemicals Co., Ltd.) as a flame retardant, and 23.2 parts by mass of maleimide resin (manufactured by Designer Molecules Inc.: trade name “DMI-7005”, Mw=49000, solid content 25% by mass) were added and mixed, and then dispersed with a three-roll mill.

Finally, 0.58 parts by mass of α,α′-bis(t-butylperoxy-m-isopropyl) benzene (manufactured by NOF CORPORATION: trade name “PERBUTYL P”) as a peroxide was blended, and stirring was performed with a magnetic stirrer.

As described above, the varnish of the resin composition of Example 1 was obtained.

### Examples 2 to 8 and Comparative Examples 1 to 3

As shown in Table I-1, a varnish of the resin composition according to Examples 2 to 8 and Comparative Examples 1 to 3 was obtained in the same manner as in Example 1, except that the PPE resin, the maleimide resin to be used, and the content thereof were changed.

The maleimide resins shown in Table I-1 are as follows.

BMI-689: Mw=689, manufactured by Designer Molecules Inc.

BMI-3000J: Mw=3000, manufactured by Designer Molecules Inc.

BMI-1500: Mw=1500, manufactured by Designer Molecules Inc.

BMI-4000: Mw=570, manufactured by Daiwa Fine Chemicals Co., Ltd.

As the organic solvent of the varnish of each resin composition, cyclohexanone was used when the branched PPE resins-1 and 2 soluble in cyclohexanone were used, and chloroform was used when the unbranched PPE resins A and B insoluble in cyclohexanone were used.

<<Evaluation>>

The varnish of the resin composition according to each of examples and each of comparative examples was evaluated as follows.

<Production of Cured Film>

A varnish of the obtained resin composition was applied onto a shine surface of a copper foil having a thickness of 18 μm with an applicator so that a cured product had a thickness of 50 μm.

Then, drying was performed at 90° C. for 30 minutes in a hot air circulating drying furnace.

Thereafter, nitrogen was completely filled by using an inert oven, heating was performed to 200° C., and then curing was performed for 60 minutes. Thereafter, the copper foil was etched to provide a cured product (cured film).

In the resin composition according to Comparative Example 3, no cured film was able to be produced.

<Environmental Response>

A varnish using cyclohexanone as a solvent was designated as “o”, and a varnish using chloroform as a solvent was designated as “x”. As described above, unbranched PPE resins were insoluble in cyclohexanone; however, branched PPE resins were soluble in cyclohexanone.

<Dielectric Properties>

The relative permittivity Dk and the dielectric loss tangent Df, which are dielectric properties, were measured according to the following method.

A cured film was cut into a length of 80 mm, a width of 45 mm, and a thickness of 50 μm to be used as a test piece, and measurement was performed by a SPDR (Split Post Dielectric Resonator) resonator method. A vector network analyzer E5071C and an SPDR resonator manufactured by Key Site Technologies were used as the measuring instrument, and a calculation program manufactured by QWED Inc. was used. The conditions were a frequency of 10 GHz and a measurement temperature of 25° C.

(Evaluation Criteria)

When Dk was less than 3.2 and Df was 0.0016 or less, evaluation was “⊚”; when Dk was less than 3.2 and Df was more than 0.0016 and less than 0.003, evaluation was “o”; and when Dk was 3.2 or more or Df was 0.003 or more, evaluation was “x”.

<Thermal Expansion Coefficient>

The produced cured film was cut into a length of 3 cm, a width of 0.3 cm, and a thickness of 50 μm, and using a TMA (Thermomechanical Analysis) Q400 manufactured by TA Instruments, Inc., the temperature was raised from 20 to 250° C. at 5° C./min under a nitrogen atmosphere with a chuck distance of 16 mm and a load of 30 mN in a tensile mode, and then the temperature was lowered from 250 to 20° C. at 5° C./min to perform the measurement. An average thermal expansion coefficient between 100° C. and 50° C. in lowering temperature was obtained.

(Evaluation criteria) When CTE (α1) was less than 30 ppm, evaluation was “o”; when CTE (α1) was 30 ppm or more and less than 40 ppm, evaluation was “Δ”; and when CTE (α1) was 40 ppm or more, evaluation was “x”.

<Heat Resistance>

The produced cured film was cut into a length of 30 mm, a width of 5 mm, and a thickness of 50 μm, and the glass transition temperature (Tg) was measured by DMA7100 (manufactured by Hitachi High-Tech Science Corporation). The temperature range was from 30 to 280° C., the temperature raising rate was 5° C./min, the frequency was 1 Hz, the strain amplitude was 7 μm, the minimum tension was 50 mN, and the distance between grips was 10 mm. The glass transition temperature (Tg) was set to a temperature at which tan 6 showed a maximum.

(Evaluation Criteria)

When the glass transition temperature (Tg) was 205° C. or more, evaluation was “⊚”, when the glass transition temperature (Tg) was 200° C. or more and less than 205° C., evaluation was “o”, and when the glass transition temperature (Tg) was less than 200° C., evaluation was “x”.

<Elongation at Break and Tensile Strength>

The produced cured film was cut into a length of 8 cm, a width of 0.5 cm, and a thickness of 50 μm, and the tensile elongation at break and the tensile strength (tensile strength at break) were measured under the following conditions.

[Measurement Conditions]

Tester: tensile tester EZ-SX (manufactured by Shimadzu Corporation)

Distance between chucks: 50 mm

Test speed: 1 mm/min

Elongation calculation: (tensile movement amount/distance between chucks)×100

(Evaluation criteria) When the tensile elongation at break was 1.4% or more and a tensile strength was 40 MPa or more, evaluation was “⊚”, when the tensile elongation at break was 1.0% or more and less than 1.4% and the tensile strength was 35 MPa or more and less than 40 MPa, evaluation was “o”, and when the tensile elongation at break was less than 1.0% or the tensile strength was less than 35 MPa, evaluation was “x”.

<Self-Extinguishing Property>

A cured film was obtained in the same manner as in the production of the cured film described above, except that application was performed with an applicator such that the thickness of the cured product was 300 μm. The produced cured film having a thickness of 300 μm was cut into a length of 125 mm and a width of 12.5 mm, a flame of a gas burner was brought into contact with the lower end of the test piece for self-extinguishing property test for 10 seconds, and a combustion duration time from the end of the flame contact to the extinction of the test piece was measured. Specifically, five test pieces were tested and the total combustion duration time was calculated.

(Evaluation Criteria) When the total combustion duration time was less than 40 seconds, evaluation was “⊚”, when the total combustion duration time was 40 seconds or more and less than 50 seconds, evaluation was “o”, and when the total combustion duration time was 50 seconds or more, evaluation was “x”.

<Water Absorbency>

A cured film was obtained in the same manner as in the production of the cured film described above, except that application was performed with an applicator such that the thickness of the cured product was 200 μm. The produced 200 μm-thick cured film was cut into a length of 50 mm and a width of 50 mm to prepare a test piece for water absorbency test. The weight of the test piece was precisely weighed (weight before water absorption) with an electronic balance, and then the test piece was immersed for 24 hours in a water bath set at 23.5° C. Thereafter, the immersed test piece was taken out, water droplets were removed with a dry cloth, and then the weight was precisely weighed (weight after water absorption) with an electronic balance. From the weight of the test piece before and after water absorption, the water absorption ratio was calculated by the following formula.

Water absorption ratio=((weight after water absorption−weight before water absorption)/weight after water absorption)×100

(Evaluation Criteria)

When the water absorption ratio was 0.06 or less, evaluation was “⊚”, when the water absorption ratio was more than 0.06 and 0.1 or less, evaluation was “o”, and when the water absorption ratio was more than 0.1, evaluation was “x”.

TABLE 1-1

| Raw material | | Example 1 | Example 2 | Example 3 | Example 4 | Example 5 | Example 6 |
|---|---|---|---|---|---|---|---|
| Thermosetting | PPE-1(Mn = 20,000) | 17.4 | 17.4 | 17.4 | | 17.4 | 17.4 |
| PPE resin | Thermosetting side | | | | | | |
| | chain type | | | | | | |
| | Conformation plot: | | | | | | |
| | 0.31 | | | | | | |
| | PPE-2(Mn = 19,000) | | | | 17.4 | | |
| | Thermosetting end type | | | | | | |
| | Conformation plot: | | | | | | |
| | 0.33 | | | | | | |
| | Unbranched PPE resin | | | | | | |
| | (Mn = 1,000) | | | | | | |
| | Unbranched PPE resin | | | | | | |
| | (Mn = 19.000) | | | | | | |
| | Conformation plot: | | | | | | |
| | 0.61 | | | | | | |
| Maleimide | DMI-7005(Mw = 49,000) | 23.2 | 46.4 | 69.6 | 23.2 | | |
| resin | Solid content 25 wt % | | | | | | |
| | BMI-689 | | | | | 5.8 | |
| | BMI 3000J(Mw = 3,000) | | | | | | 5.8 |
| | BMI-1500(Mw = 1,500) | | | | | | |
| | BMI-4000 | | | | | | |
| Crosslinking aid | TAIC | 11.6 | 11.6 | 11.6 | 11.6 | 11.6 | 11.6 |
| Inorganic filler | SC2500-SVJ | 94.4 | 94.4 | 94.4 | 94.4 | 94.4 | 94.4 |
| Styrene elastomer | H1051 | 5.7 | 5.7 | 5.7 | 5.7 | 5.7 | 5.7 |
| Flame retardant | OP-935 | 11.1 | 11.1 | 11.1 | 11.1 | 11.1 | 11.1 |
| Peroxide | Perbutyl P | 0.58 | 0.58 | 0.58 | 0.58 | 0.58 | 0.58 |
| Organic solvent | Cyclohexanone | 60 | 60 | 60 | 60 | 60 | 60 |
| | Chloroform | | | | | | |
| Environment | Evaluation | ◯ | ◯ | ◯ | ◯ | ◯ | ◯ |
| response | | | | | | | |
| Dielectric | Dk(10 GHz) | 3.0 | 3.0 | 3.1 | 3.0 | 3.0 | 3.0 |
| properties | Df(10 GHz) | 0.0017 | 0.0021 | 0.0026 | 0.0017 | 0.0016 | 0.0016 |
| | Evaluation | ◯ | ◯ | ◯ | ◯ | ⊚ | ⊚ |
| Coefficient of | CTE(ppm)α1 | 22 | 20 | 21 | 21 | 23 | 19 |
| linear expansion | Evaluation | ◯ | ◯ | ◯ | ◯ | ◯ | ◯ |
| Glass transition | Tg(° C.) | 205 | 211 | 218 | 208 | 205 | 206 |
| temperature | Evaluation | ⊚ | ⊚ | ⊚ | ⊚ | ⊚ | ⊚ |
| Mechanical | Tensile strength (MPa) | 45 | 50 | 54 | 46 | 39 | 44 |
| strength | Tensile elongation | 1.5 | 1.7 | 2.0 | 1.4 | 1.3 | 1.5 |
| | at break (%) | | | | | | |
| | Evaluation | ◯ | ◯ | ◯ | ◯ | Δ | ◯ |
| Flammability | Self-extinguishing | 37 | 35 | 33 | 37 | 39 | 39 |
| test | time (s) | | | | | | |
| | Evaluation | ⊚ | ⊚ | ⊚ | ⊚ | ⊚ | ⊚ |
| Water | Water absorption | 0.070 | 0.085 | 0.097 | 0.070 | 0.060 | 0.059 |
| absorption | ratio (%) | | | | | | |
| ratio | Evaluation | ◯ | ◯ | ◯ | ◯ | ⊚ | ⊚ |

| | | | | Comparative | Comparative | Comparative |
|---|---|---|---|---|---|---|
| Raw material | | Example 7 | Example 8 | Example 1 | Example 2 | Example 3 |
| Thermosetting | PPE-1(Mn = 20,000) | 17.4 | 17.4 | 17.4 | | |
| PPE resin | Thermosetting side | | | | | |
| | chain type | | | | | |
| | Conformation plot: | | | | | |
| | 0.31 | | | | | |
| | PPE-2(Mn = 19,000) | | | | | |
| | Thermosetting end type | | | | | |
| | Conformation plot: | | | | | |
| | 0.33 | | | | | |
| | Unbranched PPE resin | | | | 17.4 | |
| | (Mn = 1,000) | | | | | |
| | Unbranched PPE resin | | | | | 17.4 |
| | (Mn = 19.000) | | | | | |
| | Conformation plot: | | | | | |
| | 0.61 | | | | | |
| Maleimide | DMI-7005(Mw = 49,000) | | | | 23.2 | 23.2 |
| resin | Solid content 25 wt % | | | | | |
| | BMI-689 | | | | | |
| | BMI 3000J(Mw = 3,000) | | | | | |
| | BMI-1500(Mw = 1,500) | 5.8 | | | | |
| | BMI-4000 | | 5.8 | | | |
| Crosslinking aid | TAIC | 11.6 | 11.6 | 11.6 | 11.6 | 11.6 |
| Inorganic filler | SC2500-SVJ | 94.4 | 94.4 | 94.4 | 94.4 | 94.4 |
| Styrene elastomer | H1051 | 5.7 | 5.7 | 5.7 | 5.7 | 5.7 |
| Flame retardant | OP-935 | 11.1 | 11.1 | 11.1 | 11.1 | 11.1 |
| Peroxide | Perbutyl P | 0.58 | 0.58 | 0.58 | 0.58 | 0.58 |
| Organic solvent | Cyclohexanone | 60 | 60 | 60 | | |
| | Chloroform | | | | 60 | 60 |
| Environment | Evaluation | ◯ | ◯ | ⊚ | X | X |
| response | | | | | | |
| Dielectric | Dk(10 GHz) | 3.0 | 3.1 | 3.0 | 3.3 | — |
| properties | Df(10 GHz) | 0.0017 | 0.0024 | 0.0015 | 0.0032 | — |
| | Evaluation | ◯ | ◯ | ⊚ | X | — |
| Coefficient of | CTE(ppm)α1 | 20 | 21 | 33 | 26 | — |
| linear expansion | Evaluation | ◯ | ◯ | Δ | ◯ | — |
| Glass transition | Tg(° C.) | 205 | 206 | 200 | 175 | — |
| temperature | Evaluation | ⊚ | ⊚ | ◯ | X | — |
| Mechanical | Tensile strength (MPa) | 43 | 37 | 34 | 20 | — |
| strength | Tensile elongation | 1.4 | 1.1 | 0.8 | 0.5 | — |
| | at break (%) | | | | | |
| | Evaluation | ◯ | Δ | X | X | — |
| Flammability | Self-extinguishing | 39 | 39 | 46 | 42 | — |
| test | time (s) | | | | | |
| | Evaluation | ⊚ | ⊚ | ◯ | ◯ | — |
| Water | Water absorption | 0.065 | 0.092 | 0.050 | 0.110 | — |
| absorption | ratio (% | | | | | |
| ratio | Evaluation | ◯ | ◯ | ⊚ | X | — |

### Example II

<<<Production of Composition>>>

Hereinafter, the production procedure of each composition (compositions of examples 1 to 8 and comparative examples 1 to 3) will be described.

<<Synthesis of PPE Resin>>

<Branched PPE Resin-1 (Thermosetting Side Chain Type): Method 1>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied at 10 ml/min. A raw material solution was prepared by dissolving 105 g of 2,6-dimethylphenol and 13 g of 2-allylphenol, which are raw material phenols, in 1.5 L of toluene. This raw material solution was added dropwise to the flask and reacted at 40° C. for 6 hours while being stirred at a rotation speed of 600 rpm. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin-1.

The branched PPE resin-1 had a number average molecular weight of 20000 and a weight average molecular weight of 60000.

The slope of the conformation plot for the branched PPE resin-1 was 0.31.

<Branched PPE Resin-2 (Thermosetting End Type): Method 2>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied at 10 ml/min. A raw material solution was prepared by dissolving 105 g of 2,6-dimethylphenol and 4.89 g of orthocresol, which are raw material phenols, in 1.5 L of toluene. This raw material solution was added dropwise to the flask and reacted at 40° C. for 6 hours while being stirred at a rotation speed of 600 rpm. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin.

To a 1 L two-necked recovery flask equipped with a dropping funnel, 50 g of the branched PPE resin, 4.8 g of allyl bromide as a modifying compound, and 300 mL of NMP were added and stirred at 60° C. 5 mL of a 5 M aqueous NaOH solution was added dropwise to the solution. Thereafter, stirring was further performed at 60° C. for 5 hours. Then, the reaction solution was neutralized with hydrochloric acid, then reprecipitation was performed in 5 L of methanol, filtration was performed, washing was performed 3 times with a mixed solution of methanol and water in a mass ratio of 80:20, and then drying was performed at 80° C. for 24 hours to obtain a branched PPE resin-2.

The branched PPE resin-2 had a number average molecular weight of 19000 and a weight average molecular weight of 66500.

The slope of the conformation plot for the branched PPE resin-2 was 0.33.

<Unbranched PPE Resin A>

An unbranched PPE resin A was obtained based on the same synthesis method as that for the branched PPE resin-1, except that 34 mL of water was added to a raw material solution in which 7.6 g of 2-allyl-6-methylphenol and 34 g of 2,6-dimethylphenol, which are raw material phenols, were dissolved in 0.23 L of toluene.

The unbranched PPE resin A was insoluble in cyclohexanone and was soluble in chloroform.

The unbranched PPE resin A had a number average molecular weight of 1000 and a weight average molecular weight of 2000.

The slope of the conformation plot of the unbranched PPE resin A was unmeasurable.

<Unbranched PPE Resin B>

An unbranched PPE resin B was obtained based on the same synthesis method as that for the branched PPE resin-1, except for using a raw material solution obtained by dissolving 13.8 g of 2-allyl-6-methylphenol and 103 g of 2,6-dimethylphenol, which are raw material phenols, in 0.38 L of toluene.

The unbranched PPE resin B had a number average molecular weight of 19000 and a weight average molecular weight of 39900.

The slope of the conformation plot for the unbranched PPE resin B was 0.61.

The number average molecular weight (Mn) and weight average molecular weight (Mw) of each PPE resin were determined by gel permeation chromatography (GPC). In GPC, Shodex K-805L was used as a column, the column temperature was 40° C., the flow rate was 1 mL/min, the eluent was chloroform, and the standard material was polystyrene.

<Solvent Solubility of PPE Resin>

Solvent solubility of each PPE resin was confirmed.

The branched PPE resins-1 and 2 were soluble in cyclohexanone.

The unbranched PPE resins A and B were insoluble in cyclohexanone and were soluble in chloroform.

<<Preparation of Resin Composition>>

The varnish of the resin composition according to each of examples and each of comparative examples was obtained as follows.

### Example 1

To 17.4 parts by mass of a branched PPE resin-1 and 11.4 parts by mass of a styrene elastomer (Asahi Kasei Corporation: trade name “H1051”), 60 parts by mass of cyclohexanone as a solvent was added, mixed at 40° C. for 30 minutes, and stirred to complete dissolution.

To the PPE resin solution obtained in this manner, 10.4 parts by mass of TAIC (manufactured by Mitsubishi Chemical Corporation) as a crosslinkable curing agent, 94.4 parts by mass of spherical silica (manufactured by Admatechs Co., Ltd.: trade name “SC2500-SVJ”), 11.1 parts by mass of OP935 (manufactured by Clariant Chemicals Co., Ltd.) as a flame retardant, 5.8 parts by mass of maleimide resin (manufactured by Designer Molecules Inc.: trade name “BMI-3000J”, Mw=3000), and 0.83 parts by mass of 1,3,5-triazine-2,4,6-trithiol (thiocyanuric acid) were added, mixed, and then dispersed with a three-roll mill.

Finally, 0.58 parts by mass of α,α′-bis(t-butylperoxy-m-isopropyl) benzene (manufactured by NOF CORPORATION: trade name “PERBUTYL P”) as a peroxide was blended, and stirring was performed with a magnetic stirrer.

As described above, the varnish of the resin composition of Example 1 was obtained.

### Examples 2 to 8 and Comparative Examples 1 to 4

As shown in Table II-1, a varnish of the resin composition according to Examples 2 to 8 and Comparative Examples 1 to 4 was obtained in the same manner as in Example 1, except that the PPE resin to be used, the triazine-based compound, and the content thereof were changed.

As the organic solvent of the varnish of each resin composition, cyclohexanone was used when the branched PPE resins-1 and 2 soluble in cyclohexanone were used, and chloroform was used when the unbranched PPE resins A and B insoluble in cyclohexanone were used.

<<Evaluation>>

The varnish of the resin composition according to each of examples and each of comparative examples was evaluated as follows.

<Production of Cured Film>

A varnish of the obtained resin composition was applied onto a shine surface of a copper foil having a thickness of 18 μm with an applicator so that a cured product had a thickness of 50 μm.

Then, drying was performed at 90° C. for 30 minutes in a hot air circulating drying furnace.

Thereafter, nitrogen was completely filled by using an inert oven, heating was performed to 200° C., and then curing was performed for 60 minutes.

Thereafter, the copper foil was etched to provide a cured product (cured film).

In the resin composition according to Comparative Example 4, no cured film was able to be produced.

<Environmental Response>

A varnish using cyclohexanone as a solvent was designated as “o”, and a varnish using chloroform as a solvent was designated as “x”. As described above, unbranched PPE resins were insoluble in cyclohexanone; however, branched PPE resins were soluble in cyclohexanone.

<Dielectric Properties>

The relative permittivity Dk and the dielectric loss tangent Df, which are dielectric properties, were measured according to the following method.

A cured film was cut into a length of 80 mm, a width of 45 mm, and a thickness of 50 μm to be used as a test piece, and measurement was performed by a SPDR (Split Post Dielectric Resonator) resonator method. A vector network analyzer E5071C and an SPDR resonator manufactured by Key Site Technologies were used as the measuring instrument, and a calculation program manufactured by QWED Inc. was used. The conditions were a frequency of 10 GHz and a measurement temperature of 25° C.

(Evaluation Criteria)

When Dk was less than 3.1 and Df was less than 0.002, evaluation was “o”; and when Dk was 3.1 or more or Df was 0.002 or more, evaluation was “x”.

<Mechanical Strength (Elongation at Break)>

The produced cured film was cut into a length of 8 cm, a width of 0.5 cm, and a thickness of 50 μm, and the tensile elongation at break was measured under the following conditions.

[Measurement Conditions]

Tester: tensile tester EZ-SX (manufactured by Shimadzu Corporation)

Distance between chucks: 50 mm

Test speed: 1 mm/min

Elongation calculation: (tensile movement amount/distance between chucks)×100

(Evaluation Criteria) When the tensile elongation at break was 2.0% or more, evaluation was “⊚”; when the tensile elongation at break was 1.0% or more and less than 2.0%, evaluation was “o”; and when the tensile elongation at break was less than 1.0%, evaluation was “x”

<Flammability Test>

A cured film was obtained in the same manner as in the production of the cured film described above, except that application was performed with an applicator such that the thickness of the cured product was 300 μm. The produced cured film having a thickness of 300 μm was cut into a length of 125 mm and a width of 12.5 mm, a flame of a gas burner was brought into contact with the lower end of the test piece for self-extinguishing property test for 10 seconds, and a combustion duration time from the end of the flame contact to the extinction of the test piece was measured. Specifically, five test pieces were tested and the total combustion duration time was calculated.

(Evaluation Criteria)

When the total combustion duration time was less than 40 seconds, evaluation was “⊚”, when the total combustion duration time was 40 seconds or more and less than 50 seconds, evaluation was “o”, and when the total combustion duration time was 50 seconds or more, evaluation was “x”.

<Peel Strength (Adhesion)>

Peel strength (peeling strength for a low-roughness copper foil) was measured in accordance with the copper-clad laminate test standard JIS-C-6481. A resin composition was applied onto a rough surface of a low-roughness copper foil (FV-WS (manufactured by Furukawa Denki Co., Ltd.): Rz=1.5 μm) so that a cured product had a thickness of 50 μm, and drying was performed in a hot air circulating drying furnace at 90° C. for 30 minutes. Thereafter, nitrogen was completely filled by using an inert oven, heating was performed to 200° C., and then curing was performed for 60 minutes. An epoxy adhesive (araldite) was applied onto the obtained cured film side, a copper clad laminate (length of 150 mm, width of 100 mm, and thickness of 1.6 mm) was placed thereon, and curing was performed in a hot air circulating drying furnace at 60° C. for 1 hour. Then, a cut having a width of 10 mm and a length of 100 mm was made in the low-roughness copper foil portion, and one end thereof was peeled off and gripped with a gripper to measure 90° peel strength.

[Measurement Conditions]

Tester: tensile tester EZ-SX (manufactured by Shimadzu Corporation)

Measurement temperature: 25° C.

Stroke: 35 mm

Stroke speed: 50 mm/min

Number of measurements: calculation of average value of 5 times

(Evaluation Criteria)

When the peel strength was 5 N/cm or more, evaluation was “o”; when the peel strength was 4 N/cm or more and less than 5 N/cm, evaluation was “A”; and when the peel strength was less than 4 N/cm, evaluation was “x”.

TABLE II-1

| Raw material | | | Example 1 | Example 2 | Example 3 | Example 4 | Example 5 | Example 6 | Example 7 |
|---|---|---|---|---|---|---|---|---|---|
| Thermosetting | | PPE-1(Mn = 20,000) | 17.4 | | 17.4 | 17.4 | 17.4 | 17.4 | 17.4 |
| PPE resin | | Thermosetting side | | | | | | | |
| | | chain type | | | | | | | |
| | | Conformation plot: | | | | | | | |
| | | 0.31 | | | | | | | |
| | | PPE-2(Mn = 1 [symbol] ,000) | | 17.4 | | | | | |
| | | Thermosetting [symbol] | | | | | | | |
| | | Conformation plot: | | | | | | | |
| | | 0.33 | | | | | | | |
| | | [symbol] | | | | | | | |
| | | [symbol] | | | | | | | |
| [symbol] | [symbol] compound | TAIC | 10. [symbol] | 10. [symbol] | 10. [symbol] | 10. [symbol] | 10. [symbol] | 10. [symbol] | 10. [symbol] |
| | Triazines | [symbol] acid | [symbol] | [symbol] | [symbol] | [symbol] | [symbol] | | |
| | having a | [symbol] | | | | | | [symbol] | |
| | thiol group | [symbol] | | | | | | | [symbol] |

| | | | | | | | | |
|---|---|---|---|---|---|---|---|---|
| Maleimide resin | [symbol] | [symbol] | [symbol] | [symbol] | 5.8 | 5.8 | [symbol] | [symbol] |
| Inorganic filler | SC2500-SVJ | [symbol] | [symbol] | [symbol] | [symbol] | [symbol] | [symbol] | [symbol] |
| Styrene elastomer | H1051 | 11. [symbol] | 11. [symbol] | 11. [symbol] | 11. [symbol] | 11. [symbol] | 11. [symbol] | 11. [symbol] |
| Flame retardant | OP-935 | 11.1 | 11.1 | 11.1 | 11.1 | 11.1 | 11.1 | 11.1 |
| Peroxide | Perbutyl P | [symbol] .58 | [symbol] | [symbol] | [symbol] | [symbol] | [symbol] | [symbol] |
| Organic | [symbol] | [symbol] | [symbol] | [symbol] | [symbol] | [symbol] | 60 | 60 |
| solvent | Chloroform | | | | | | | |
| Environment | Evaluation | ◯ | ◯ | ◯ | ◯ | ◯ | ◯ | ◯ |
| response | | | | | | | | |
| Dielectric | [symbol] | [symbol] | [symbol] | [symbol] | [symbol] | [symbol] | [symbol] | [symbol] |
| properties | [symbol] | [symbol] | [symbol] | [symbol] | [symbol] | [symbol] | [symbol] | [symbol] |
| | [symbol] | ◯ | ◯ | ◯ | ◯ | ◯ | ◯ | ◯ |
| Peel | [symbol] | [symbol] | [symbol] | [symbol] | [symbol] | [symbol] | [symbol] | [symbol] |
| strength | Evaluation | ◯ | ◯ | ◯ | ◯ | ◯ | ◯ | ◯ |
| Mechanical | [symbol] | [symbol] | [symbol] | 2.6 | 2.3 | [symbol] | [symbol] | [symbol] |
| strength | Evaluation | [symbol] | [symbol] | [symbol] | [symbol] | [symbol] | [symbol] | [symbol] |
| Flammability | [symbol] | [symbol] | [symbol] | [symbol] | [symbol] | [symbol] | [symbol] | [symbol] |
| test | Evaluation | [symbol] | [symbol] | [symbol] | [symbol] | [symbol] | [symbol] | [symbol] |

| | | | | Comparative | Comparative | Comparative | Comparative |
|---|---|---|---|---|---|---|---|
| Raw Material | | | Example 8 | Example [symbol] | Example [symbol] | Example [symbol] | Example [symbol] |
| Thermosetting | | PPE-1(Mn = 20,000) | 17.4 | 17.4 | | 17.4 | |
| PPE resin | | Thermosetting side | | | | | |
| | | chain type | | | | | |
| | | Conformation plot: | | | | | |
| | | 0.31 | | | | | |
| | | PPE-2(Mn = 1 [symbol] ,000) | | | | | |
| | | Thermosetting [symbol] | | | | | |
| | | Conformation plot: | | | | | |
| | | 0.33 | | | | | |
| | | [symbol] | | | 17.4 | | |
| | | [symbol] | | | | | 17.4 |
| [symbol] | [symbol] compound | TAIC | | 10. [symbol] | 10. [symbol] | | 10. [symbol] |
| | Triazines | [symbol] acid | [symbol] | | [symbol] | | [symbol] |
| | having a | [symbol] | | | | | |
| | thiol group | [symbol] | | | | | |

| | | | | | | |
|---|---|---|---|---|---|---|
| Maleimide resin | [symbol] | [symbol] | [symbol] | [symbol] | [symbol] 8 | [symbol] 8 |
| Inorganic filler | SC2500-SVJ | [symbol] | [symbol] | [symbol] | [symbol] | [symbol] |
| Styrene elastomer | H1051 | 11. [symbol] | 11. [symbol] | 11. [symbol] | 11. [symbol] | 11. [symbol] |
| Flame retardant | OP-935 | 11.1 | 11.1 | 11.1 | 11.1 | 11.1 |
| Peroxide | Perbutyl P | [symbol] | 0.58 | [symbol] | [symbol] | 0. [symbol] |
| Organic | [symbol] | 60 | 60 | | | |
| solvent | Chloroform | | | 60 | [symbol] | [symbol] |
| Environment | Evaluation | ◯ | ◯ | X | ◯ | [symbol] |
| response | | | | | | |
| Dielectric | [symbol] | [symbol] | [symbol] | [symbol] | [symbol] | — |
| properties | [symbol] | [symbol] | [symbol] | [symbol] | [symbol] | — |
| | [symbol] | ◯ | ◯ | X | X | — |
| Peel | [symbol] | [symbol] | [symbol] | [symbol] | [symbol] | — |
| strength | Evaluation | ◯ | Δ | X | X | — |
| Mechanical | [symbol] | [symbol] | [symbol] | 0.8 | 2.1 | — |
| strength | Evaluation | [symbol] | ◯ | X | ◯ | — |
| Flammability | [symbol] | [symbol] | [symbol] | [symbol] | [symbol] | — |
| test | Evaluation | ◯ | ◯ | ◯ | ◯ | — |

[symbol]

indicates data missing or illegible when filed

### Example III

<<<Production of Resin Composition>>>

Hereinafter, the production procedure of each resin composition (compositions of Examples 1 to 4 and Comparative Examples 1 and 2) will be described.

<<Synthesis of PPE>>

<Branched PPE>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied. A raw material solution was prepared by dissolving 100 g of 2,6-dimethylphenol and 12.2 g of 2-allylphenol, which are raw material phenols, in 1.5 L of toluene. This raw material solution was added dropwise to the flask and reacted at 40° C. for 6 hours while being stirred. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin.

The branched PPE had a number average molecular weight of 15000 and a weight average molecular weight of 55000.

The terminal hydroxyl group of the branched PPE had a hydroxyl value of 5 (hydroxyl group amount: 0.33 mmol/g).

The slope of the conformation plot for the branched PPE was 0.33.

<Unbranched PPE>

Synthesis was performed in the same procedure as in the branched PPE, except that 4.5 g of 2-allyl-6-methylphenol and 33 g of 2,6-dimethylphenol were used as raw material phenols, and 0.23 L of toluene was used as a solvent.

The slope of the conformation plot was 0.61.

The unbranched PPE had a number average molecular weight of 19000 and a weight average molecular weight of 38000.

The terminal hydroxyl group of the unbranched PPE had a hydroxyl value of 1 (hydroxyl group amount: 0.07 mmol/g).

The slope of the conformation plot for the unbranched PPE was 0.61.

<Solvent Solubility of PPE>

Solvent solubility of each PPE resin was confirmed. The evaluation of this solvent solubility is as described above.

The branched PPE was soluble in cyclohexanone.

The unbranched PPE was insoluble in cyclohexanone and was soluble in chloroform.

<<Preparation of Resin Composition>>

The varnish of the resin composition according to each of examples and each of comparative examples was obtained as follows.

### Example 1

13.25 parts by mass of branched PPE, 4.42 parts by mass of EPOCROS (details will be described later) as a reactive styrene copolymer, 13.25 parts by mass of TAIC (manufactured by Mitsubishi Chemical Corporation) as a crosslinkable curing agent, 6.2 parts by mass of Tuftec H1051 (manufactured by Asahi Kasei Corporation) as an adhesion imparting agent, and 100 parts by mass of cyclohexanone were added and stirred.

To the obtained solution including PPE, 58.4 parts by mass of spherical silica (manufactured by Admatechs Co., Ltd.: trade name “SC2500-SVJ”) as an inorganic filler was added, mixed, and then dispersed with a three-roll mill.

Finally, 0.53 parts by mass of α,α′-bis(t-butylperoxy-m-isopropyl) benzene (manufactured by NOF CORPORATION: trade name “PERBUTYL P”) as a peroxide was blended, and stirring was performed with a magnetic stirrer.

As described above, the resin composition of Example 1 was obtained.

### Examples 2 to 4 and Comparative Examples 1 and 2

As shown in Table III-1, the resin composition according to Examples 2 to 4 and Comparative Examples 1 and 2 was obtained in the same manner as in Example 1, except that the PPE resin to be used, the polystyrene copolymer, and the content thereof were changed.

The reactive styrene copolymer shown in Table III-1 is as follows.

Trade name: EPOCROS (manufactured by Nippon Shokubai Co., Ltd.)

Oxazoline group-containing styrene copolymer

Number average molecular weight: 70000

PDI: 2.28

Amount of oxazoline group: 0.27 mmol/g

Trade name: SMA resin (manufactured by Nippon Shokubai Co., Ltd.)

Acid anhydride group (maleic anhydride group)-containing styrene copolymer

Weight average molecular weight: 14400

Amount of acid anhydride group: 0.27 mmol/g

As the organic solvent of each resin composition, cyclohexanone was used when the branched PPE soluble in cyclohexanone was used, and chloroform was used when the unbranched PPE insoluble in cyclohexanone was used.

<<Evaluation>>

The resin composition according to each of examples and each of comparative examples was evaluated as follows.

<Production of Cured Film>

The obtained resin composition was applied onto a shine surface of a copper foil having a thickness of 18 μm with an applicator so that a cured product had a thickness of 50 μm.

Then, drying was performed at 90° C. for 30 minutes in a hot air circulating drying furnace.

Thereafter, nitrogen was completely filled by using an inert oven, heating was performed to 200° C., and then curing was performed for 60 minutes. Thereafter, the copper foil was etched to provide a cured product (cured film).

<Environmental Response>

A resin composition using cyclohexanone as a solvent was designated as “o”, and a resin composition using chloroform as a solvent was designated as “x”. As described above, unbranched PPE was insoluble in cyclohexanone; however, branched PPE was soluble in cyclohexanone.

<Dielectric Properties>

The relative permittivity Dk and the dielectric loss tangent Df, which are dielectric properties, were measured according to the following method.

A cured film thus produced was cut into a length of 80 mm, a width of 45 mm, and a thickness of 50 μm to be used as a test piece, and measurement was performed by a SPDR (Split Post Dielectric Resonator) resonator method. A vector network analyzer E5071C and an SPDR resonator manufactured by Key Site Technologies were used as the measuring instrument, and a calculation program manufactured by QWED Inc. was used. The conditions were a frequency of 10 GHz and a measurement temperature of 25° C.

(Evaluation Criteria) When Df was 0.002 or less, evaluation was “⊚”; when Df was more than 0.002 and less than 0.003, evaluation was “o”; and when Df was 0.003 or more, evaluation was “x”

<Tensile Strength>

The produced cured film was cut into a length of 8 cm, a width of 0.5 cm, and a thickness of 50 μm, and the tensile strength (tensile strength at break) was measured under the following conditions.

[Measurement Conditions]

Tester: tensile tester EZ-SX (manufactured by Shimadzu Corporation)

Distance between chucks: 50 mm

Test speed: 1 mm/min

(Evaluation Criteria)

When the tensile strength was 45 MPa or more, evaluation was “⊚”; when the tensile strength was 30 MPa or more and less than 45 MPa, evaluation was “o”; and when the tensile strength was less than 30 MPa, evaluation was “x”

<Peel Strength (Adhesion)>

Adhesion (peeling strength for a low-roughness copper foil) was measured in accordance with the copper-clad laminate test standard JIS-C-6481.

Each of the resin compositions was applied onto a rough surface of a low-roughness copper foil (FV-WS (manufactured by Furukawa Denki Co., Ltd.): Rz=1.5 μm) so that a cured product had a thickness of 50 μm, and drying was performed in a hot air circulating drying furnace at 90° C. for 30 minutes. Thereafter, nitrogen was completely filled by using an inert oven, heating was performed to 200° C., and then curing was performed for 60 minutes. An epoxy adhesive (araldite) was applied onto the obtained cured film side, a copper clad laminate (length of 150 mm, width of 100 mm, and thickness of 1.6 mm) was placed thereon, and curing was performed in a hot air circulating drying furnace at 60° C. for 1 hour. Then, a cut having a width of 10 mm and a length of 100 mm was made in the low-roughness copper foil portion, and one end thereof was peeled off and gripped with a gripper to measure 900 peel strength.

[Measurement Conditions]

Tester: tensile tester EZ-SX (manufactured by Shimadzu Corporation)

Measurement temperature: 25° C.

Stroke: 35 mm

Stroke speed: 50 mm/min

Number of measurements: calculation of average value of 5 times

When the 90° peel strength was 5.0 N/cm or more, evaluation was “⊚”; when the 90° peel strength was 3.0 N/cm or more and less than 5.0 N/cm, evaluation was “o”; and when the 90° peel strength was less than 3.0 N/cm, evaluation was “x”.

TABLE III-1

| | | | | | | Comparative | Comparative |
|---|---|---|---|---|---|---|---|
| Composition | | Example 1 | Example 2 | Example 3 | Example 4 | Example [symbol] | Example [symbol] |
| PPE resin | Branched PPE | 13. [symbol] | 13. [symbol] 5 | 13. [symbol] 5 | 13. [symbol] 5 | | |
| | Mn = 15000 | | | | | | |
| | (2,6-DMP:2-AP = | | | | | | |
| | 90:10) | | | | | | |
| | Number of terminal | | | | | | |
| | hydroxyl groups: | | | | | | |
| | 5 (0.33 nmol/g) | | | | | | |
| | Slop of | | | | | | |
| | conformation plot: | | | | | | |
| | 0.33 | | | | | | |
| | Unbranched PPE | | | | | 13.25 | 13.25 |
| | Mn = 19000 | | | | | | |
| | (2,6-DMP:2AMP = | | | | | | |
| | 90:10) | | | | | | |
| | Slop of | | | | | | |
| | conformation plot: | | | | | | |
| | 0.61 | | | | | | |
| Crosslinkable copolymer | EPOCROS | 4.12 | 13. [symbol] 5 | | | [symbol] .65 | |
| having [symbol] | Mn = 70,000 | | | | | | |
| group [symbol] | (manufactured by | | | | | | |
| of [symbol] with | [symbol] Co., Ltd.) | | | | | | |
| hydroxyl group | 0.27 mmol/g | | | | | | |
| | [symbol] resin | | | 1. [symbol] | 5.14 | | 1.03 |
| | Mw = 14,400 | | | | | | |
| | (manufactured by | | | | | | |
| | Kawa [symbol] chemical | | | | | | |
| | Co., Ltd.) | | | | | | |
| | 0. [symbol] mmol/g | | | | | | |
| Peroxide | Perbutyl P | 0. [symbol] | 0. [symbol] | 0. [symbol] | 0. [symbol] | 0. [symbol] | 0. [symbol] |
| | (manufactured by [symbol] ) | | | | | | |
| [symbol] | TAIC | 13.2 [symbol] | 13.25 | 13.25 | 13.25 | 13.25 | 13. [symbol] |
| curing agent | (manufactured by | | | | | | |
| | [symbol] Chemical | | | | | | |
| | Corporation) | | | | | | |
| Adhesion | [symbol] | 6.2 | 6.2 | 6.2 | 6.2 | 6.2 | 6.2 |
| [symbol] | (manufacturedd by | | | | | | |
| agent | [symbol] Corporation) | | | | | | |
| Inorganic | SC2500-SVJ | [symbol] .4 | [symbol] .4 | [symbol] | [symbol] | [symbol] | [symbol] |
| filler | (manufactured by | | | | | | |
| | [symbol] Co., Ltd.) | | | | | | |
| Solvent | Cyclohexanone | 100 | 100 | 100 | 100 | | |
| | Chloroform | | | | | 100 | 100 |
| Environment response | | ⊚ | ⊚ | ⊚ | ⊚ | X | X |
| Electrical | Dk 10 GHz | 2.71 | 2.4 [symbol] | 2.72 | 2. [symbol] 3 | 2. [symbol] | 2. [symbol] |
| properties | Df 10 GHz | 0.0014 | 0.0014 | 0.0014 | 0.001 [symbol] | 0.00 [symbol] | 0.001 |
| | Evaluation | ⊚ | ⊚ | ⊚ | ⊚ | X | X |
| Mechanical | Tensile strength (MPa) | 51 | [symbol] | 49 | [symbol] | [symbol] | 14 |
| properties | Evaluation | ⊚ | ⊚ | ⊚ | ⊚ | X | X |
| Peeling strength | Peel strength N/cm | [symbol] | [symbol] | [symbol] | [symbol] | 2.9 | 2.8 |
| for low- | Evaluation | ⊚ | ⊚ | ⊚ | ⊚ | X | X |
| roughness [symbol] | | | | | | | |

[symbol]

indicates data missing or illegible when filed

### Example IV

<<<Production of Resin Composition>>>

Hereinafter, the production procedure of each resin composition (compositions of Examples 1 to 6 and Comparative Examples 1 and 2) will be described.

<<Synthesis of PPE>>

<Branched PPE>

In a 3 L two-necked recovery flask, 2.6 g of di-μ-hydroxo-bis[(N,N,N′,N′-tetramethylethylenediamine) copper (II)] chloride (Cu/TMEDA) and 3.18 mL of tetramethylethylenediamine (TMEDA) were added and sufficiently dissolved, and oxygen was supplied. A raw material solution was prepared by dissolving 100 g of 2,6-dimethylphenol and 12.2 g of 2-allylphenol, which are raw material phenols, in 1.5 L of toluene. This raw material solution was added dropwise to the flask and reacted at 40° C. for 6 hours while being stirred. After completion of the reaction, reprecipitation was performed with a mixed solution of 20 L of methanol and 22 mL of concentrated hydrochloric acid, filtration was performed, and drying was performed at 80° C. for 24 hours to obtain a branched PPE resin.

The branched PPE had a number average molecular weight of 15000 and a weight average molecular weight of 55000.

The terminal hydroxyl group of the branched PPE had a hydroxyl value of 5 (hydroxyl group amount: 0.33 mmol/g).

The slope of the conformation plot for the branched PPE was 0.33.

<Unbranched PPE>

Synthesis was performed in the same procedure as in the branched PPE, except that 4.5 g of 2-allyl-6-methylphenol and 33 g of 2,6-dimethylphenol were used as raw material phenols, and 0.23 L of toluene was used as a solvent.

The slope of the conformation plot was 0.61.

The unbranched PPE had a number average molecular weight of 19000 and a weight average molecular weight of 38000.

The terminal hydroxyl group of the unbranched PPE had a hydroxyl value of 1 (hydroxyl group amount: 0.07 mmol/g).

The slope of the conformation plot for the unbranched PPE was 0.61.

<Solvent solubility of PPE>

Solvent solubility of each PPE resin was confirmed. The evaluation of this solvent solubility is as described above.

The branched PPE was soluble in cyclohexanone.

The unbranched PPE was insoluble in cyclohexanone and was soluble in chloroform.

<<Preparation of Resin Composition>>

The resin composition according to each of examples and each of comparative examples was obtained as follows.

### Example 1

11.93 parts by mass of the branched PPE, 13.25 parts by mass of TAIC (manufactured by Mitsubishi Chemical Corporation) as a crosslinkable curing agent, 6.2 parts by mass of Tuftec H1051 (manufactured by Asahi Kasei Corporation) as an adhesion imparting agent, and 100 parts by mass of cyclohexanone were added and stirred. To the obtained solution including PPE, 1.33 parts by mass of crosslinked polystyrene-based particles (trade name: “SBX”, particle size: 0.8 μm, shape: true sphere, specific gravity: 1.06, manufactured by Sekisui Kasei Co., Ltd.), and 58.4 parts by mass of spherical silica (trade name “SC2500SVJ” manufactured by Admatechs Co., Ltd.) as a filler component were added and mixed, and then dispersed with a three-roll mill.

Finally, 0.53 parts by mass of α,α′-bis(t-butylperoxy-m-isopropyl) benzene (manufactured by NOF CORPORATION: trade name “PERBUTYL P”) as a peroxide was blended, and stirring was performed with a magnetic stirrer.

As described above, the resin composition of Example 1 was obtained.

### Examples 2 to 9 and Comparative Examples 1 and 2

As shown in Table IV-1, the resin composition according to Examples 2 to 9 and Comparative Examples 1 and 2 was obtained in the same manner as in Example 1, except that the PPE to be used, the filler component, and the content of each component were changed.

As the organic solvent of each resin composition, cyclohexanone was used when the branched PPE soluble in cyclohexanone was used, and chloroform was used when the unbranched PPE insoluble in cyclohexanone was used.

<<Evaluation>>

The resin composition according to each of examples and each of comparative examples was evaluated as follows.

<Production of Cured Film>

The obtained resin composition was applied onto a shine surface of a copper foil having a thickness of 18 μm with an applicator so that a cured product had a thickness of 50 μm.

Then, drying was performed at 90° C. for 30 minutes in a hot air circulating drying furnace.

Thereafter, nitrogen was completely filled by using an inert oven, heating was performed to 200° C., and then curing was performed for 60 minutes. Thereafter, the copper foil was etched to provide a cured product (cured film).

<Environmental Response>

A resin composition using cyclohexanone as a solvent was designated as “o”, and a resin composition using chloroform as a solvent was designated as “x”. As described above, unbranched PPE was insoluble in cyclohexanone; however, branched PPE was soluble in cyclohexanone.

<Dielectric Properties>

The relative permittivity Dk and the dielectric loss tangent Df, which are dielectric properties, were measured according to the following method.

A cured film thus produced was cut into a length of 80 mm, a width of 45 mm, and a thickness of 50 μm to be used as a test piece, and measurement was performed by a SPDR (Split Post Dielectric Resonator) resonator method. A vector network analyzer E5071C and an SPDR resonator manufactured by Key Site Technologies were used as the measuring instrument, and a calculation program manufactured by QWED Inc. was used. The conditions were a frequency of 10 GHz and a measurement temperature of 25° C.

(Evaluation Criteria)

When Df was less than 0.0015, evaluation was “⊚”; when Df was 0.0015 or more and less than 0.002, evaluation was “o”; and when Df was 0.002 or more, evaluation was “x”

<Heat Resistance>

As an index of heat resistance, a glass transition temperature (Tg) was measured by TMA measurement. The glass transition temperature (Tg) was measured according to the following method.

While using “TMA/SS120” manufactured by Hitachi High-Tech Science Corporation as a measurement apparatus, measurement was performed on a test piece having length 1 cm, width 0.3 cm, and thickness 50 μm, under the conditions of a temperature raising rate of 5° C./min, and a measurement temperature range of 30 to 250° C.

(Evaluation Criteria)

When Tg was 205° C. or more, evaluation was “⊚”; when Tg was 190° C. or more and less than 205° C., evaluation was “o”; and when Tg was less than 190° C., evaluation was “x”

<Crosslinking Density>

The crosslinking density (n) was determined by cutting the cured film into a length of 1 cm, a width of 0.3 cm, and a thickness of 50 μm, performing a dynamic viscoelasticity test with the following measuring apparatus and measurement conditions to obtain E′ (storage elastic modulus) and E″ (loss elastic modulus), and using the following formula.

Measuring apparatus: DMA7100 manufactured by Hitachi High Tech Science Corporation Measurement conditions: measurement temperature of 20 to 300° C.

Temperature raising rate: 5° C./min

Frequency: 1 and 10 Hz

Deformation mode: tensile/sinusoidal mode

Calculation formula: n (mol/cc)=E′min/(3ΦRT×1000)

wherein n represents a crosslinking density, E′min represents a minimum value of the storage elastic modulus E′, Φ represents a front coefficient (Φ≈1), R represents a gas constant of 8.31 (J/mol·K), and T represents an absolute temperature of E′min.

(Evaluation Criteria)

When the crosslinking density was 20 mol/cc or more, evaluation was “⊚”; when the crosslinking density was 10 mol/cc or more and less than 20 mol/cc, evaluation was “o”; and when the crosslinking density was less than 10 mol/cc, evaluation was “x”.

<Elongation at Break and Tensile Strength>

The cured film was cut into a length of 8 cm, a width of 0.5 cm, and a thickness of 50 μm, and the tensile elongation at break and tensile strength were measured under the following conditions.

[Measurement Conditions]

Tester: tensile tester EZ-SX (manufactured by Shimadzu Corporation)

Distance between chucks: 50 mm

Test speed: 1 mm/min

Elongation calculation: (tensile movement amount/distance between chucks)×100

When tensile elongation at break was 1% or more, evaluation was “⊚”; when was 0.5 or more and less than 1%, evaluation was “o”; and when was less than 0.5, evaluation was “x”.

When the tensile strength was 45 MPa or more, evaluation was “⊚”; when the tensile strength was 30 MPa or more and less than 45 MPa, evaluation was “o”; and when the tensile strength was less than 30 MPa, evaluation was “x”.

TABLE IV-1

| | | Exam- | Exam- | Exam- | Exam- | Exam- | Exam- | Exam- | Exam- | Exam- | | |
|---|---|---|---|---|---|---|---|---|---|---|---|---|
| | | ple | ple | ple | ple | ple | ple | ple | ple | ple | | |
| Composition | | [symbol] | [symbol] | [symbol] | [symbol] | [symbol] | [symbol] | [symbol] | [symbol] | [symbol] | [symbol] | [symbol] |
| Polyphenylene | Branched PPE | [symbol] | [symbol] | [symbol] | [symbol] | [symbol] | [symbol] | [symbol] | [symbol] | [symbol] | | |
| ether | Mn = 15000 | | | | | | | | | | | |
| | (2,6-DMP:2-AP = | | | | | | | | | | | |
| | 90.10) | | | | | | | | | | | |
| | Slop of | | | | | | | | | | | |
| | conformation | | | | | | | | | | | |
| | plot: 0.33 | | | | | | | | | | | |
| | Unbranced PPE | | | | | | | | | | [symbol] | [symbol] |
| | Mn = 19000 | | | | | | | | | | | |
| | (2,6-DMP:2AMP = | | | | | | | | | | | |
| | 90:10) | | | | | | | | | | | |
| | Slop of | | | | | | | | | | | |
| | conformation | | | | | | | | | | | |
| | plot: 0.61 | | | | | | | | | | | |
| | Fine particle | [symbol] | [symbol] | [symbol] | [symbol] | [symbol] | [symbol] | [symbol] | [symbol] | [symbol] | [symbol] | [symbol] |
| | SBX 0. [symbol] μm | | | | | | | | | | | |
| | (manufactured | | | | | | | | | | | |
| | by SEKISUI | | | | | | | | | | | |
| | CHEMICAL | | | | | | | | | | | |
| | CO., LTD.) | | | | | | | | | | | |
| Filler | [symbol] | [symbol] | [symbol] | [symbol] | [symbol] | [symbol] | [symbol] | [symbol] | [symbol] | [symbol] | [symbol] | [symbol] |
| component | [symbol] | | | | | | [symbol] | | | | | |
| | [symbol] | | | | | | | [symbol] | | | | |
| | [symbol] | | | | | | | | [symbol] | | | |
| | [symbol] | | | | | | | | | [symbol] | | |
| Peroxide | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] | [symbol] | [symbol] | [symbol] | [symbol] |
| Solvent | [symbol] | [symbol] | [symbol] | [symbol] | [symbol] | [symbol] | [symbol] | [symbol] | [symbol] | [symbol] | | |
| | Chloroform | | | | | | | | | | [symbol] | [symbol] |
| Environment response | | [symbol] | [symbol] | [symbol] | [symbol] | [symbol] | [symbol] | [symbol] | [symbol] | [symbol] | [symbol] | [symbol] |
| Electrical | Dk 10 GHz | [symbol] | [symbol] | [symbol] | [symbol] | [symbol] | [symbol] | [symbol] | [symbol] | [symbol] | [symbol] | [symbol] |
| properties | Df 10 GHz | [symbol] | [symbol] | [symbol] | [symbol] | [symbol] | [symbol] | [symbol] | [symbol] | [symbol] | [symbol] | [symbol] |
| | Evaluation | [symbol] | [symbol] | [symbol] | [symbol] | [symbol] | [symbol] | [symbol] | [symbol] | [symbol] | X | X |
| Heat | [symbol] | [symbol] | [symbol] | [symbol] | [symbol] | [symbol] | [symbol] | [symbol] | [symbol] | [symbol] | [symbol] | [symbol] |
| resistance | Evaluation | [symbol] | [symbol] | [symbol] | [symbol] | [symbol] | [symbol] | [symbol] | [symbol] | [symbol] | X | X |
| Crosslinking | Crosslinking | [symbol] | [symbol] | [symbol] | [symbol] | [symbol] | [symbol] | [symbol] | [symbol] | [symbol] | [symbol] | [symbol] |
| density | density ( [symbol] / [symbol] ) | | | | | | | | | | | |
| | Evaluation | [symbol] | [symbol] | [symbol] | [symbol] | [symbol] | [symbol] | [symbol] | [symbol] | [symbol] | X | X |
| Mechanical | Elongation at | [symbol] | [symbol] | [symbol] | [symbol] | [symbol] | [symbol] | [symbol] | [symbol] | [symbol] | [symbol] | [symbol] |
| properties | break (%) | | | | | | | | | | | |
| | Evaluation | [symbol] | [symbol] | [symbol] | [symbol] | [symbol] | [symbol] | [symbol] | [symbol] | [symbol] | X | X |
| | [symbol] | [symbol] | [symbol] | [symbol] | [symbol] | [symbol] | [symbol] | [symbol] | [symbol] | [symbol] | [symbol] | [symbol] |
| | Evaluation | [symbol] | [symbol] | [symbol] | [symbol] | [symbol] | [symbol] | [symbol] | [symbol] | [symbol] | X | X |

[symbol]

indicates data missing or illegible when filed

1: A curable composition, comprising:
a polyphenylene ether having a functional group including an unsaturated carbon bond; and
at least one of a compound including at least one maleimide group in one molecule, a triazine-based compound including at least one thiol group, and crosslinked polystyrene particles,
wherein the polyphenylene ether is obtained from raw material phenols including phenols, and having less than 0.6 of a slope calculated by a conformation plot, and the phenols in the raw material phenols have a hydrogen atom at an ortho position and a para position.

2: A curable composition according to claim 1, further comprising:
a styrene copolymer,
wherein the polyphenylene ether further includes a hydroxyl group, and the styrene copolymer has a functional group which reacts with the hydroxyl group in the polyphenylene ether.

3: The curable composition according to claim 1, further comprising:
trialkenyl isocyanurate.

4: A dry film or a preproduction obtained by a process comprising applying the curable composition of claim 1 onto a base material or impregnating a base material with the curable composition of claim 1.

5: A cured product obtained by a process comprising curing the curable composition of claim 1.

6: A laminated board, comprising:
the cured product of claim 5.

7: An electronic component, comprising:
the cured product of claim 5.

8: The curable composition according to claim 2, further comprising:
trialkenyl isocyanurate.

9: A dry film or a preproduction obtained by a process comprising applying the curable composition of claim 1 onto a base material.

10: A dry film or a preproduction obtained by a process comprising impregnating a base material with the curable composition of claim 1.

11: A cured product obtained by a process comprising curing the curable composition of claim 2.

12: A laminated board, comprising:
the cured product of claim 11.

13: An electronic component, comprising:
the cured product of claim 11.

14: A dry film or a preproduction obtained by a process comprising applying the curable composition of claim 2 onto a base material.

15: A dry film or a preproduction obtained by a process comprising impregnating a base material with the curable composition of claim 2.

16: A cured product obtained by a process comprising curing the curable composition of claim 3.

17: A laminated board, comprising:
the cured product of claim 16.

18: An electronic component, comprising:
the cured product of claim 16.

19: A dry film or a preproduction obtained by a process comprising applying the curable composition of claim 3 onto a base material.

20: A dry film or a preproduction obtained by a process comprising impregnating a base material with the curable composition of claim 3.
